(19) United States
(12) Patent Application Publication
(10) Pub. No.: US 2026/0003566 A1
(43) Pub. Date: Jan. 1, 2026

(54) MAPPING AUDIO CHANNELS FOR PLAYBACK WITHIN A VENUE

(71) Applicant: Sphere Entertainment Group, LLC, New York, NY (US)

(72) Inventors: Erik HOCKMAN, New York, NY (US); Christopher Daniel BAINE, Fairfax, VA (US); Jonathan Hendrik KREBS, Berlin (DE); Evert W. START, Zeist (NL)

(73) Assignee: Sphere Entertainment Group, LLC, New York, NY (US)

(21) Appl. No.: 19/251,328

(22) Filed: Jun. 26, 2025

Related U.S. Application Data
(60) Provisional application No. 63/665,954, filed on Jun. 28, 2024.

(51) Int. Cl. G06F 3/16; G06F 3/01; G06F 3/04842

(52) U.S. Cl. CPC G06F 3/165; G06F 3/011; G06F 3/04842

(57) ABSTRACT

Systems, methods, and apparatuses disclosed herein can simulate the playback of audio and/or video of an event hosted at a real-world venue within a virtual environment. These systems, methods, and apparatuses can assign, or map, discrete audio input channels onto composite audio output channels associated with the real-world venue. These systems, methods, and apparatuses can simulate the playback of these composite audio output channels in the virtual environment to evaluate the fidelity of these composite audio output channels at various monitoring locations within the real-world venue. This allows audio professionals to remotely adjust, modify, or refine these composite audio output channels without being physically present at the venue.

### CROSS-REFERENCE TO RELATED APPLICATIONS

The present application claims the benefit of U.S. Provisional Patent Application No. 63/665,954, filed Jun. 28, 2024, which is incorporated herein by reference in its entirety.

### BACKGROUND

In live event production and venue-based audio installations, achieving optimal sound quality across various listening positions is a complex and time-intensive task. Typically, sound engineers, audio engineers, event designers, or the like need to be physically present at the venue to evaluate how the mix of audio channels is perceived at different locations, such as the front of house, audience areas, or backstage. This process often requires multiple setup iterations, sound checks, and real-time adjustments during rehearsals or live events. Conventional audio monitoring tools are generally limited to signal metering, waveform inspection, or isolated playback of individual audio channels through headphones or studio monitors. These tools do not provide accurate spatial or acoustical feedback that reflects how a composite mix would be perceived in a specific acoustic environment, such as a theater, concert hall, or open-air venue. As a result, sound engineers, audio engineers, event designers, or the like lack the means to perform reliable off-site evaluation and pre-configuration of complex audio systems prior to on-site deployment.

### BRIEF DESCRIPTION OF THE FIGURES

The accompanying drawings, which are incorporated herein and form part of the specification, illustrate the disclosure and, together with the description, further serve to explain the principles of the disclosure and enable a person of skill in the relevant art(s) to make and use the disclosure.

FIG. 1 illustrates a high-level pictorial representation of an exemplary audio simulation system in accordance with some exemplary embodiments of the present disclosure;

FIG. 2A illustrates a block diagram of an exemplary audio mapping tool that can be incorporated within the exemplary audio simulation system in accordance with some exemplary embodiments of the present disclosure;

FIG. 2B illustrates a flowchart for the exemplary audio mapping tool in accordance with various embodiments;

FIG. 3A and FIG. 3B graphically illustrate exemplary virtual models of an exemplary real-world venue that can be incorporated within the exemplary audio simulation system in accordance with some exemplary embodiments of the present disclosure;

FIG. 4A through FIG. 4E graphically illustrate other exemplary virtual models of an exemplary real-world venue that can be incorporated within the exemplary audio simulation system in accordance with some exemplary embodiments of the present disclosure;

FIG. 5A through FIG. 5C graphically illustrate exemplary operations of the exemplary audio simulation system in accordance with some exemplary embodiments of the present disclosure;

FIG. 6 graphically illustrates another exemplary virtual model of the exemplary real-world venue that can be incorporated within the exemplary audio simulation system in accordance with some exemplary embodiments of the present disclosure;

FIG. 7A and FIG. 7B graphically illustrate exemplary operations of an exemplary audio monitoring tool that can be incorporated within the exemplary audio simulation system in accordance with some exemplary embodiments of the present disclosure;

FIG. 8 illustrates a flowchart for the exemplary audio monitoring tool in accordance with various embodiments; and

FIG. 9 graphically illustrates a simplified block diagram of a computing device that can be incorporated within the exemplary audio simulation system according to some embodiments of the present disclosure.

The disclosure is described with reference to the accompanying drawings. In the drawings, generally, like reference numbers indicate identical or functionally similar elements. Additionally, generally, the left-most digit(s) of a reference number identifies the drawing in which the reference number first appears.

### DETAILED DESCRIPTION

The following disclosure presents various embodiments and examples to illustrate different features of the subject matter. Specific examples of components and configurations are described to simplify understanding, but these are provided solely for illustration and are not intended to limit the scope of the disclosure. Aspects of the disclosure are best understood by reading the detailed description alongside the accompanying figures. Reference numerals and/or letters may be repeated across different examples; such repetition does not imply any specific relationship between the various embodiments or configurations. Additionally, consistent with industry standards, features in the figures are not drawn to scale, dimensions may be exaggerated or minimized to enhance clarity in discussion.

### Overview

Systems, methods, and apparatuses disclosed herein can simulate the playback of audio and/or video of an event hosted at a real-world venue within a virtual environment. These systems, methods, and apparatuses can assign, or map, discrete audio input channels onto composite audio output channels associated with the real-world venue. These systems, methods, and apparatuses can simulate the playback of these composite audio output channels in the virtual environment to evaluate the fidelity of these composite audio output channels at various monitoring locations within the real-world venue. This allows sound engineers, audio engineers, event designers, or the like, herein referred to as audio professionals, to remotely adjust, modify, or refine these composite audio output channels without being physically present at the venue.

### Exemplary Audio Simulation System

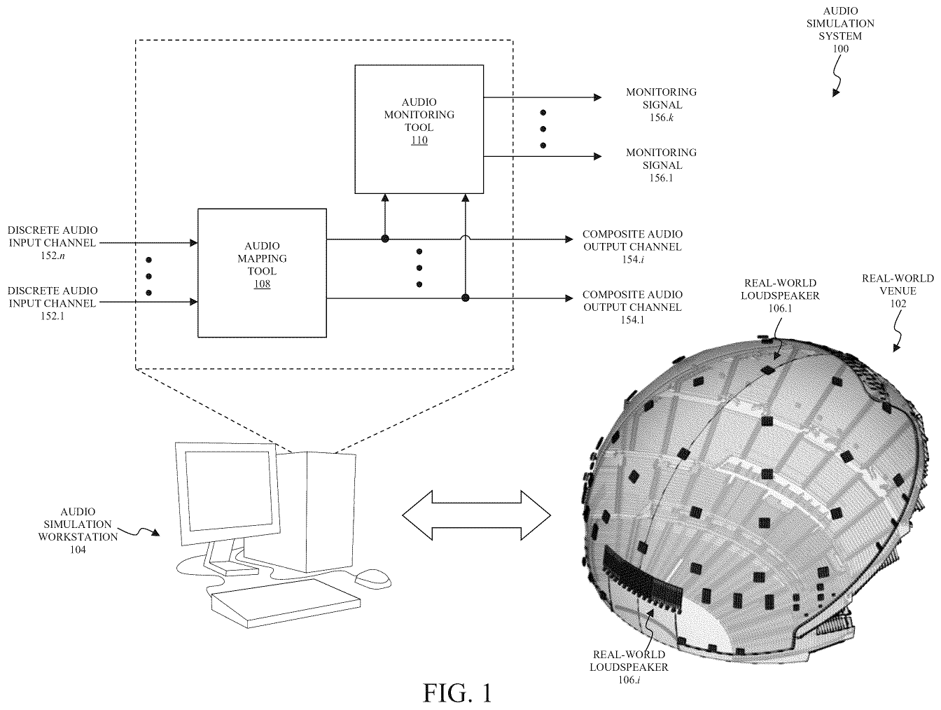

FIG. 1 illustrates a high-level pictorial representation of an exemplary audio simulation system in accordance with some exemplary embodiments of the present disclosure. In the exemplary embodiment illustrated in FIG. 1, an audio simulation system 100 can simulate playback of an event being hosted by a real-world venue 102. For example, the real-world venue 102 can represent a music real-world venue, for example, a music theater, a music club, and/or a concert hall, a sporting real-world venue, for example, an arena, a convention center, and/or a stadium, and/or any other suitable real-world venue that will be apparent to those skilled in the relevant art(s) without departing the spirit and scope of the present disclosure. And as another example, the event can represent a musical event, a theatrical event, a sporting event, a motion picture, and/or any other suitable event that will be apparent to those skilled in the relevant art(s) without departing the spirit and scope of the present disclosure. In some embodiments, the audio simulation system 100 can simulate playback of audio and/or video of the event that is being hosted by a real-world venue 102. As described herein, the audio simulation system 100 can simulate the playback of the audio and/or the video of the event in a virtual environment. In some embodiments, the audio simulation system 100 advantageously allows audio professionals to adjust, modify, refine, or the like the playback of the audio within the real-world venue 102 without being physically present at the real-world venue 102. Because these audio professionals need not be physically present at the real-world venue 102, these audio professionals can develop the presentation of multiple events simultaneously using the audio simulation system 100. As described herein, the audio simulation system 100 can execute an audio mapping tool 108 to seamlessly manage and/or route the audio that is associated with the event for playback within the real-world venue 102. As illustrated in FIG. 1, the audio simulation system 100 can assign, or map, discrete audio input channels 152.1 through 152.n onto composite audio output channels 154.1 through 154.i that are associated with the real-world venue 102 for playback. And as described herein, the audio simulation system 100 can execute an audio monitoring tool 110 to playback the composite audio output channels 154.1 through 154.i. As illustrated in FIG. 1, the audio monitoring tool 110 can monitor the composite audio output channels 154.1 through 154.i to assess the fidelity of the audio, for example, accuracy and/or quality, to be played back by the real-world venue 102. In some embodiments, the audio simulation system 100 can include an audio simulation workstation 104.

In the exemplary embodiment illustrated in FIG. 1, the real-world venue 102 can playback the video and/or the audio that is associated with the event. In some embodiments, the real-world venue 102 can represent a three-dimensional (3D) structure, for example, a hemisphere structure, also referred to as a hemispherical dome. In some embodiments, the real-world venue 102 can include a three-dimensional (3D) media plane that is spread across the interior of the real-world venue 102 to playback the video that is associated with the event. Generally, the three-dimensional (3D) media plane refers to one or more surfaces or structures within the real-world venue 102 that serve as platforms for projecting or displaying the video that is associated with the event. In some embodiments, the three-dimensional (3D) media plane can include a 19,000 by 13,500 LED visual display wrapping around the interior of a spherical structure, a spherical-like structure, a hemispherical structure, also referred to as a hemispherical dome, or a hemispherical-like structure, among others. Alternatively or additionally, the three-dimensional (3D) media plane can be part of a virtual environment, for example, a virtual reality (VR) environment, an augmented reality (AR) environment, and the like.

And as illustrated in FIG. 1, the real-world venue 102 can include real-world loudspeakers 106.1 through 106.i to playback the audio that is associated with the event. In some embodiments, the real-world loudspeakers 106.1 through 106.i can include a proscenium array loudspeaker system that is situated at, or near, a proscenium of the real-world venue 102, one or more effects extensions array loudspeaker systems that are situated at, or near, the proscenium array real-world loudspeaker system, and/or one or more environmental array loudspeaker systems that are situated throughout the real-world venue 102. In some embodiments, the proscenium array real-world loudspeaker system, the one or more effects extensions array loudspeaker systems, and/or the one or more environmental array loudspeaker systems can include one or more one or more real-world loudspeakers that can include one or more super tweeters, one or more tweeters, one or more mid-range speakers, one or more woofers, one or more subwoofers, and/or one or more full-range speakers. In some embodiments, the composite audio output channels 154.1 through 154.i can be associated with corresponding one or more real-world loudspeakers from among the real-world loudspeakers 106.1 through 106.i. In these embodiments, the composite audio output channels 154.1 through 154.i can provide audio signals for playback by the corresponding one or more real-world loudspeakers. These audio signals be represent as digital values, analog waveforms, and/or or protocol-specific messages, among others.

In the exemplary embodiment illustrated in FIG. 1, the audio simulation workstation 104, an exemplary embodiment of which is to be described in further detail below, can execute the audio mapping tool 108 and/or the audio monitoring tool 110 as described herein. Although the audio simulation workstation 104 is illustrated as being a computer workstation in FIG. 1, this is for exemplary purposes only. Those skilled in the relevant art(s) will recognize that the audio simulation workstation 104 can be any suitable electrical, mechanical, and/or electro-mechanical device that can execute the audio mapping tool 108 and/or the audio monitoring tool 110. This suitable electrical, mechanical, and/or electro-mechanical device can include, without limitation, a supercomputer, a mainframe computer, a minicomputer, a personal computer (PC), a laptop, or notebook, computer, a smartphone, an embedded computer, a server, a wearable computer, and/or a gaming console, among others. The audio mapping tool 108 and/or the audio monitoring tool 110, which are to be described in further detail below, can represent one or more software tools that can be executed by one or more electrical, mechanical, and/or electro-mechanical devices that will be apparent to those skilled in the relevant art(s) without departing from the spirit and scope of the present disclosure. Those skilled in the relevant art(s) will recognize that embodiments of the disclosure described herein may be implemented in hardware, firmware, software, or any combination thereof without departing from the present disclosure. Further, those skilled in the relevant art(s) will recognize that firmware, software, routines, instructions, or the like may be described herein as performing certain actions. However, it should be appreciated that such descriptions are merely for convenience and that such actions in fact result from one or more electrical, mechanical, and/or electro-mechanical devices executing the firmware, software, routines, instructions, or the like. Alternatively, or in addition to, those skilled in the relevant art(s) will recognize that embodiments of the disclosure described herein may also be implemented as instructions stored on a machine-readable medium, which may be read and executed by one or more processors without departing from the present disclosure. A machine-readable medium may include any mechanism for storing in a form readable by a machine, such as, without limitation, a computing device. For example, a machine-readable medium may include read only memory (ROM), random access memory (RAM), magnetic disk storage media, optical storage media, flash memory devices, and the like.

In the exemplary embodiment illustrated in FIG. 1, the audio simulation workstation 104 can assign, or map, the discrete audio input channels 152.1 through 152.n onto the composite audio output channels 154.1 through 154.i. Generally, the discrete audio input channels 152.1 through 152.n refer to discrete signal pathways having audio signals representing sounds generated by a variety of audio sources, including electronic, mechanical, and/or electro-mechanical devices, as well as natural sources. In some embodiments, these electronic, mechanical, and/or electro-mechanical devices can include a simple musical instrument, such as, without limitation, a snare drum, and/or more complicated collections of musical instruments, such as, without limitation, a standard drum kit having a snare drum, a bass drum, one or more tom-toms, one or more cymbals, and/or one or more hi-hat cymbals. In these embodiments, this simple musical instrument can include a percussion instrument, a wind instrument, a string instrument, and/or an electronic instrument. In these embodiments, these collections of musical instruments can include musical instruments from the same classification of musical instruments, such as, without limitation, percussion instruments, wind instruments, string instruments, and/or electronic instruments and/or from different classifications of musical instruments. Alternatively, or in addition to, these natural sources can include natural audio sounds generated by non-human organisms and/or human organisms, such as, without limitation, musical audio sounds produced with the human voice, often referred to as vocals. These natural audio sounds can also include natural, non-biological sources, such as, without limitation, water and/or thunder.

As illustrated in FIG. 1, the audio simulation workstation 104 can execute the audio mapping tool 108 to assign, or map, the discrete audio input channels 152.1 through 152.n onto the composite audio output channels 154.1 through 154.i. As described herein, the audio mapping tool 108 can perform a multi-stage assignment, or mapping, to assign, or map, the discrete audio input channels 152.1 through 152.n onto the composite audio output channels 154.1 through 154.i. Generally, this multi-stage assignment, or mapping, can include: assigning, or mapping, the discrete audio input channels 152.1 through 152.n to virtual mapping locations within the virtual model; assigning, or mapping, these virtual mapping locations to corresponding virtual loudspeakers; associating the virtual loudspeakers to real-world loudspeakers; and assigning, or mapping, these real-world loudspeakers to the composite audio output channels 154.1 through 154.i. This layered approach ensures an accurate and traceable routing of audio signals from the discrete audio input channels 152.1 through 152.n to physical playback on the discrete audio input channels 152.1 through 152.n.

In the exemplary embodiment illustrated in FIG. 1, the audio mapping tool 108 can assign, or map, the discrete audio input channels 152.1 through 152.n onto one or more corresponding virtual mapping locations from among multiple virtual mapping locations that are incorporated within a virtual model of the real-world venue 102 in the virtual environment. In some embodiments, the audio mapping tool 108 can access a virtual model of the real-world venue 102 in a virtual environment. In these embodiments, the virtual model of the real-world venue 102 can be characterized as being a computer-generated model of the real-world venue 102 in the virtual environment. For example, the virtual model of the real-world venue 102 can be derived from photogrammetry, Light Detection and Ranging (LiDAR) scans, architectural Computer-Aided Design (CAD) data, and/or other spatial mapping techniques, among others, to generate the virtual model of the real-world venue 102 that preserves the physical dimensions, material characteristics, and/or acoustic profiles, among others, of the real-world venue 102. In some embodiments, the audio mapping tool 108 can identify the one or more corresponding virtual mapping locations from the virtual model of the real-world venue 102. Generally, the virtual mapping locations represent one or more two-dimensional (2D) and/or three-dimensional (3D) locations within the virtual model of the real-world venue 102.

After assigning, or mapping, the discrete audio input channels 152.1 through 152.n onto the one or more corresponding virtual mapping locations, the audio mapping tool 108 can identify one or more virtual loudspeakers from among the virtual loudspeakers that correspond to these corresponding virtual mapping locations within the virtual model of the real-world venue 102 in some embodiments. In some embodiments, these virtual loudspeakers refer to graphical and functional representations of physical loudspeakers, such as one or more of the real-world loudspeakers 106.1 through 106.i, within the virtual model of the real-world venue 102 in the virtual environment. In these embodiments, these virtual loudspeakers can be associated with specific spatial locations, defined in two-dimensions (2D) or three-dimensions (3D), within the virtual model of the venue. This spatial positioning effectively mirrors the positioning of the one or more of the real-world loudspeakers 106.1 through 106.i within the real-world venue 102. In some embodiments, the audio mapping tool 108 can identify these virtual loudspeakers that correspond to these corresponding virtual mapping locations using, for example, geometric proximity and/or zone-based logic, among others. In these embodiments, the audio mapping tool 108 can identify these virtual loudspeakers that are spatially proximate to these corresponding virtual mapping locations. In some embodiments, the virtual model of the real-world venue 102 can be divided into predefined acoustic zones, with each acoustic zones being associated with one or more virtual loudspeakers from among the virtual loudspeakers. In these embodiments, the audio mapping tool 108 can identify the predefined acoustic zones having these corresponding virtual mapping locations and identify these virtual loudspeakers that are associated with these predefined acoustic zones. For example, the audio mapping tool 108 can identify the one or more virtual loudspeakers from among the virtual loudspeakers that are closest to these corresponding virtual mapping locations. After identifying the one or more virtual loudspeakers, the audio mapping tool 108 can assign, or map, the one or more corresponding virtual mapping locations to these virtual loudspeakers in the virtual environment.

After assigning, or mapping, the one or more corresponding virtual mapping locations to these virtual loudspeakers, the audio mapping tool 108 can associate these virtual loudspeakers with one or more corresponding real-world loudspeakers from among the real-world loudspeakers 106.1 through 106. In some embodiments, the audio mapping tool 108 can associate these virtual loudspeakers with the one or more corresponding real-world loudspeakers based on predefined identifiers or metadata. This association may be achieved using a stored mapping database or lookup table that links each virtual loudspeaker from among the virtual loudspeakers to one or more real-world loudspeakers from among the real-world loudspeakers 106.1 through 106.i by matching spatial coordinates, loudspeaker zones, and/or configuration data, among others.

After associating these virtual loudspeakers with these corresponding real-world loudspeakers, the audio mapping tool 108 can assign, or map, these corresponding real-world loudspeakers with one or more composite audio output channels from among the composite audio output channels 154.1 through 154.i to effectively assign, or map, the discrete audio input channels 152.1 through 152.n onto the composite audio output channels 154.1 through 154.i. In some embodiments, the audio mapping tool 108 can associate these corresponding real-world loudspeakers with the one or more composite audio output channels based on predefined identifiers or metadata. This association may be achieved using a stored mapping database or lookup table that links each real-world loudspeaker from among the real-world loudspeakers 106.1 through 106.i to one or more composite audio output channels from among the composite audio output channels 154.1 through 154.i by matching configuration parameters such as, without limitation, loudspeaker ID, spatial coordinates within the real-world venue 102, assigned zones within the real-world venue 102, or predefined channel groupings established for the real-world venue 102.

In some embodiments, the audio mapping tool 108 can develop one or more organized collections of data, often referred to as one or more databases that include the assignment, or the mapping, of the discrete audio input channels 152.1 through 152.n to their corresponding composite audio output channels from among the composite audio output channels 154.1 through 154.i. In these embodiments, the one or more databases may include one or more data tables having data values, such as, without limitation, alphanumeric strings, integers, decimals, floating points, dates, times, binary values, Boolean values, and/or enumerations.

As illustrated in FIG. 1, the audio simulation workstation 104 can execute the audio monitoring tool 110 to playback the composite audio output channels 154.1 through 154.i. In some embodiments, the audio monitoring tool 110 can playback the composite audio output channels 154.1 through 154.i to assess the fidelity of the audio to be played back through the real-world venue 102. In these embodiments, the audio monitoring tool 110 can monitor the composite audio output channels 154.1 through 154.i to assess the fidelity of the audio, for example, accuracy and/or quality, to be played back through the real-world venue 102. As part of this playing back, the audio monitoring tool 110 can access the virtual model of the real-world venue 102 in the virtual environment in a substantially similar manner as the audio mapping tool 108. As part of this playing back, the audio monitoring tool 110 can identify one or more virtual monitoring locations within the virtual model of the real-world venue 102 to simulate the playback of the composite audio output channels 154.1 through 154.i at these virtual monitoring locations. In some embodiments, the one or more virtual monitoring locations represent two-dimensional (2D) locations and/or three-dimensional (3D) locations within the virtual model of the real-world venue 102. In some embodiments, the audio monitoring tool 110 can simulate the playback of the composite audio output channels 154.1 through 154.i through the virtual loudspeakers to the one or more virtual monitoring locations. As part of this simulating, these virtual loudspeakers can generate one or more virtual soundwaves in the virtual environment that correspond to the composite audio output channels 154.1 through 154.i. In some embodiments, these virtual soundwaves represent virtual representations of the audio signals that are carried on the composite audio output channels 154.1 through 154.i. Thereafter, the audio monitoring tool 110 can simulate the propagation of these virtual soundwaves through the virtual model to the one or more virtual monitoring locations in the virtual environment to effectively monitor the composite audio output channels 154.1 through 154.i at the one or more virtual monitoring locations. In some embodiments, the one or more virtual soundwaves represent various soundwaves as the soundwaves would be received, for example, heard, at the one or more virtual monitoring locations. In some embodiments, this simulation of the propagation of these virtual soundwaves can consider one or more acoustical properties of the real-world loudspeakers 106.1 through 106.i, such as, without limitation, sensitivity, magnitude, phase, frequency, and/or directivity, among others, and/or one or more acoustical properties of the real-world venue 102, such as, without limitation, speed of sound, absorption, reflection, reverberation, transmission loss, diffraction, frequency response, impedance, resonance, and/or diffusion, among others. In some embodiments, the audio monitoring tool 110 can estimate one or more acoustical characteristics, such as, without limitation, time delay, sound pressure level, sound power, direct sound impulse response, and/or diffuse field response, among others, of the one or more virtual soundwaves at the one or more virtual monitoring locations. In these embodiments, the audio monitoring tool 110 can estimate one or more acoustical characteristics of the one or more virtual soundwaves in relation to, for example, the virtual loudspeakers and/or one another, among others, at the one or more virtual monitoring locations.

As illustrated in FIG. 1, the audio monitoring tool 110 can render one or more monitoring output signals 156.1 through 156.k corresponding to the one or more virtual soundwaves as perceived at the one or more virtual monitoring locations to enable playback of the composite audio output channels 154.1 through 154.i through headphones or loudspeakers. In some embodiments, the audio monitoring tool 110 can render one or more monitoring output signals 156.1 through 156.k is based on the one or more acoustical characteristics of the one or more virtual soundwaves at the one or more virtual monitoring locations. By applying these acoustical characteristics during rendering, the audio monitoring tool 110 can tool synthesizes the one or more monitoring output signals 156.1 through 156.k to replicate the acoustical environment of the real-world venue 102 to provide an accurate and immersive auditory representation. This beneficially allows audio professionals to physically hear the composite audio output channels 154.1 through 154.i. at the one or more virtual monitoring locations to evaluate the composite audio output channels 154.1 through 154.i as perceived at specific spatial locations associated with these virtual monitoring locations in the real-world venue. As such, these audio professionals can evaluate the composite audio output channels 154.1 through 154.i as if the composite audio output channels 154.1 through 154.i were being played back at the real-world venue 102 without these audio professionals being physically present at the real-world venue 102.

### Exemplary Audio Mapping Tool

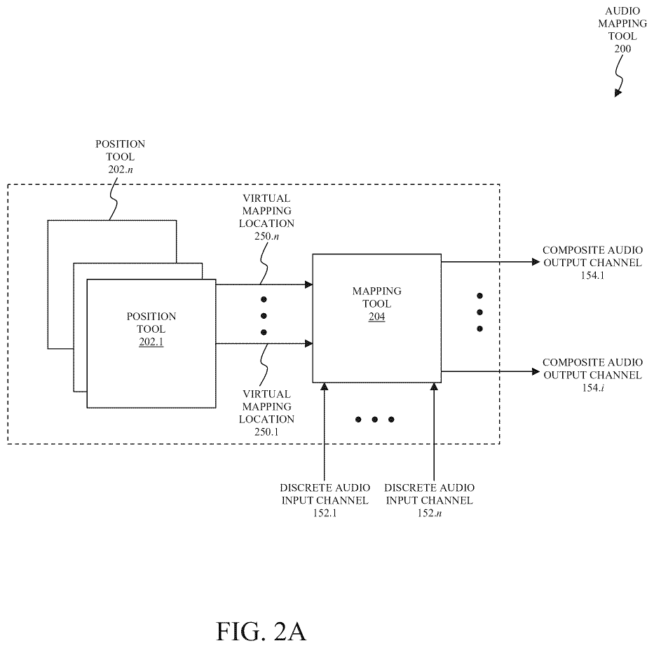

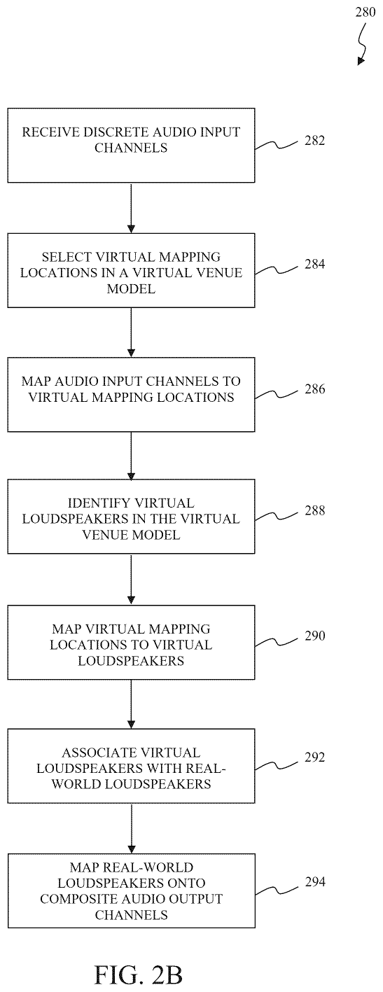

FIG. 2A illustrates a block diagram of an exemplary audio mapping tool that can be incorporated within the exemplary audio simulation system in accordance with some exemplary embodiments of the present disclosure. As described herein, an audio mapping tool 200 can seamlessly manage and/or route the audio that is associated with an event for playback within the real-world venue 102. As illustrated in FIG. 2A, the audio mapping tool 200 can assign, or map, the discrete audio input channels 152.1 through 152.n onto the composite audio output channels 154.1 through 154.i. The audio mapping tool 200 can be executed on one or more suitable electrical, mechanical, and/or electro-mechanical devices, such as, without limitation, the audio simulation workstation 104. In some embodiments, these suitable electrical, mechanical, and/or electro-mechanical devices can be standalone devices to allow audio professionals to assign, or map, the discrete audio input channels 152.1 through 152.n onto the composite audio output channels 154.1 through 154.i without these audio professionals being physically present at the real-world venue. As illustrated in FIG. 2A, the audio mapping tool 200 can include position tools 202.1 through 202.n and a mapping tool 204. The position tools 202.1 through 202.n and the mapping tool 204, which are to be described in further detail below, can represent one or more software tools that can be executed by one or more electrical, mechanical, and/or electro-mechanical devices that will be apparent to those skilled in the relevant art(s) without departing from the spirit and scope of the present disclosure. The audio mapping tool 200 can represent an exemplary embodiment of the audio mapping tool 108.

The position tools 202.1 through 202.n serve as visual assistants that supports audio professionals in assigning, or mapping, the discrete audio input channels 152.1 through 152.n onto the composite audio output channels 154.1 through 154.i. In some embodiments, the position tools 202.1 through 202.n can access the virtual model of the real-world venue 102 as described herein in a virtual environment. In these embodiments, the position tools 202.1 through 202.n can render the virtual model of the real-world venue 102 in two dimensions or three dimensions to create a spatially accurate representation of the real-world venue 102 in the virtual environment allowing audio professionals to visually explore, navigate, and interact with the virtual model of the real-world venue 102. In some embodiments, the position tools 202.1 through 202.n can visually represent the virtual loudspeakers and their spatial positions within the virtual model of the venue 102.

In the exemplary embodiment illustrated in FIG. 2A, the audio professionals can interact with the virtual model of the real-world venue 102 being rendered by the position tools 202.1 through 202.n to identify virtual mapping locations 250.1 through 250.n for the discrete audio input channels 152.1 through 152.n. In some embodiments, each position tool from among the position tools 202.1 through 202.n can identify a corresponding virtual mapping location from among the virtual mapping locations 250.1 through 250.n for each discrete audio input channel from among the discrete audio input channels 152.1 through 152.n. In some embodiments, the position tools 202.1 through 202.n can identify two-dimensional (2D) or three-dimensional (3D) coordinates of the virtual mapping locations 250.1 through 250.n within the virtual model of the real-world venue 102. In these embodiments, the position tools 202.1 through 202.n can provide these coordinates to the mapping tools 204 to assign the discrete audio input channels 152.1 through 152.n to the virtual mapping locations 250.1 through 250.n. Generally, the virtual mapping locations 250.1 through 250.n represent two-dimensional (2D) and/or three-dimensional (3D) locations within the virtual model of the real-world venue 102. In some embodiments, the position tools 202.1 through 202.n can incorporate a virtual pointing device that is controllable by the audio professionals to enable precise selection of the virtual mapping locations 250.1 through 250.n within the virtual environment. In these embodiments, the virtual pointing device can be visually represented as a cursor, crosshair, three-dimension manipulator, and/or region selector, among others, and can support zooming, panning, and/or rotation, among other, of the virtual model of the real-world venue 102 to facilitate accurate placement in spatially complex scenes. In some embodiments, the position tools 202.1 through 202.n supports intuitive user interactions such as, without limitation, “point and click” and/or “drag and drop” interactions with the virtual pointing device allowing audio professionals to easily control the virtual pointing device to identify the virtual mapping locations 250.1 through 250.n within the virtual model of the real-world venue 102. In these embodiments, the audio professionals can control the virtual pointing device using a graphical user interface (GUI), mouse, touchscreen, stylus, or other input device to enable precise and dynamic selection and placement of the virtual mapping locations 250.1 through 250.n within the virtual model of the real-world venue 102.

In the exemplary embodiment illustrated in FIG. 2A, the mapping tools 204 can assign, or map, the virtual mapping locations 250.1 through 250.n to the virtual loudspeakers in the virtual environment as described herein. In some embodiments, the mapping tools 204 can provide the assigning, or mapping, of the virtual mapping locations 250.1 through 250.n to the virtual loudspeakers to the position tools 202.1 through 202.n for rendering onto the virtual model of the real-world venue 102. In these embodiments, the audio professionals can interact with the virtual model of the real-world venue 102 being rendered by the position tools 202.1 through 202.n to select the virtual loudspeakers in the virtual environment to highlight the discrete audio input channels 152.1 through 152.n assigned to these virtual loudspeakers. Alternatively, or in addition to, the audio professionals can interact with the virtual model of the real-world venue 102 being rendered by the position tools 202.1 through 202.n to select the discrete audio input channels 152.1 through 152.n in the virtual environment to highlight the virtual loudspeakers assigned to the discrete audio input channels 152.1 through 152.n.

Moreover, the mapping tools 204.1 through 204.n can associate these virtual loudspeakers with one or more real-world loudspeakers from among the real-world loudspeakers 106.1 through 106.i then assign, or map, these real-world loudspeakers to the composite audio output channels 154.1 through 154.i as described herein. In some embodiments, the mapping tools 204 can provide the assigning, or mapping, of these virtual loudspeakers to the composite audio output channels 154.1 through 154.i to the position tools 202.1 through 202.n for rendering onto the virtual model of the real-world venue 102. In these embodiments, the audio professionals can interact with the virtual model of the real-world venue 102 being rendered by the position tools 202.1 through 202.n to select the virtual loudspeakers in the virtual environment to highlight the composite audio output channels 154.1 through 154.i assigned to these virtual loudspeakers. Alternatively, or in addition to, the audio professionals can interact with the virtual model of the real-world venue 102 being rendered by the position tools 202.1 through 202.n to select the composite audio output channels 154.1 through 154.i in the virtual environment to highlight the virtual loudspeakers assigned to the composite audio output channels 154.1 through 154.i.

FIG. 2B illustrates a flowchart for the exemplary audio mapping tool in accordance with various embodiments. The disclosure is not limited to this operational description. Rather, it will be apparent to ordinary persons skilled in the relevant art(s) that other operational control flows are within the scope and spirit of the present disclosure. The following discussion describes an exemplary operational control flow 290 for assigning, or mapping, the discrete audio input channels 152.1 through 152.n onto the composite audio output channels 154.1 through 154.i that are associated with the real-world venue 102. In the exemplary embodiment illustrated in FIG. 2B, the operational control flow 280 can be performed by the exemplary audio mapping tool, such as, without limitation, the audio mapping tool 108 and/or the audio mapping tool 108, executing on an exemplary audio simulation workstation, such as, without limitation, the audio simulation workstation 104. In the exemplary embodiment illustrated in FIG. 2B, the operational control flow 280 can ensure that the assignment of the discrete audio input channels 152.1 through 152.n is accurate, consistent, and optimized, thereby enabling precise and expressive real-time audio control across diverse venue configurations. In some embodiments, the operational control flow 290 allows audio professionals to assign, or map, the discrete audio input channels 152.1 through 152.n onto the composite audio output channels 154.1 through 154.i without these audio professionals being physically present at a real-world venue, such as, without limitation, the real-world venue 102.

At operation 282, the operational control flow 280 receives the discrete audio input channels 152.1 through 152.n. Each discrete audio input channel from among the discrete audio input channels 152.1 through 152.n represents an independent audio signal pathway carrying a unique audio stream. These audio streams may originate from a diverse array of sources, including but not limited to electronic instruments, such as, without limitation, synthesizers, samplers; mechanical devices such as, without limitation, clockwork-based tone generators; electro-mechanical transducers such as, without limitation, pickups or piezoelectric sensors embedded in physical objects, as well as naturally occurring sound sources, such as, without limitation, speech, ambient field recordings. Each discrete audio input channel from among the discrete audio input channels 152.1 through 152.n can maintain isolation from the others to preserve the fidelity and spatial integrity of the individual audio content.

At operation 284, the operational control flow 280 selects one or more virtual mapping locations in a virtual model. The operational control flow 280 can define these virtual mapping locations within a virtual model of the real-world venue. In some embodiments, these virtual mapping locations correspond to precise coordinates or volumetric regions in two-dimensional (2D) or three-dimensional (3D) space within the virtual model. The virtual model can incorporate the geometry, surface material properties, and spatial acoustics of the real-world venue to enable accurate modeling of direct sound paths, early reflections, and/or reverberation effects, among others.

At operation 286, the operational control flow 280 assigns, or maps, the discrete audio input channels 152.1 through 152.n to the one or more virtual mapping locations from operation 284. In some embodiments, this mapping, or assigning, can be executed using fixed positional assignments, dynamic routing algorithms, or user-defined spatial automation. In these embodiments, the goal is to simulate the perceived origin of the discrete audio input channels 152.1 through 152.n within the virtual model so that each discrete audio input channel from among the discrete audio input channels 152.1 through 152.n appears to emanate from the one or more virtual mapping locations from operation 284. In these embodiments, the mappings, or assignments, may also include metadata such as, without limitation, source orientation, divergence, or movement trajectories to enhance spatial realism.

At operation 288, the operational control flow 280 identifies one or more virtual loudspeakers in the virtual model that are associated with the virtual mapping locations from operation 286. In some embodiments, the one or more virtual loudspeakers refer to graphical and functional representations of physical loudspeakers, such as one or more of the real-world loudspeakers 106.1 through 106.i, within the virtual model of the real-world venue 102 in the virtual environment. In these embodiments, these virtual loudspeakers can be associated with specific spatial locations, defined in two-dimensions (2D) or three-dimensions (3D), within the virtual model of the venue. This spatial positioning effectively mirrors the positioning of the one or more of the real-world loudspeakers 106.1 through 106.i within the real-world venue 102.

At operation 290, the operational control flow 280 assigns, or maps, the virtual mapping locations from operation 286 to one or more virtual loudspeakers from among the one or more virtual loudspeakers from operation 288. In some embodiments, this mapping, or assigning, can involves spatial audio rendering algorithms, such as, without limitation, without limitation Vector Base Amplitude Panning (VBAP), Higher-Order Ambisonics (HOA), and/or Head-Related Transfer Function (HRTF)-based binaural processing, among others, to translate the corresponding virtual mapping locations into audio signals suitable for simulation by the one or more virtual loudspeakers.

At operation 292, the operational control flow 280 associates the one or more virtual loudspeakers from operation 292 with one or more real-world loudspeakers from among the real-world loudspeakers 106.1 through 106.i. In some embodiments, the operational control flow 280 can associate the one or more virtual loudspeakers from operation 292 with the one or more real-world loudspeakers based on predefined identifiers or metadata. This association may be achieved using a stored mapping database or lookup table that links each virtual loudspeaker from among the one or more virtual loudspeakers from operation 292 to the one or more real-world loudspeakers by matching spatial coordinates, loudspeaker zones, and/or configuration data, among others.

At operation 294, the operational control flow 280 assigns, or maps, the one or more real-world loudspeakers from operation 292 onto the composite audio output channels 154.1 through 154.i to effectively assign, or map, the discrete audio input channels 152.1 through 152.n onto the composite audio output channels 154.1 through 154.i. In some embodiments, the operational control flow 280 can associate the one or more real-world loudspeakers from operation 292 with the composite audio output channels 154.1 through 154.i based on predefined identifiers or metadata. This association may be achieved using a stored mapping database or lookup table that links the one or more real-world loudspeakers from operation 292 to the composite audio output channels 154.1 through 154.i by matching configuration parameters such as, without limitation, loudspeaker ID, spatial coordinates within the real-world venue 102, assigned zones within the real-world venue 102, or predefined channel groupings established for the real-world venue 102.

Exemplary Virtual Model of an Exemplary Real-World Venue that can be Incorporated within the Exemplary Audio Simulation System

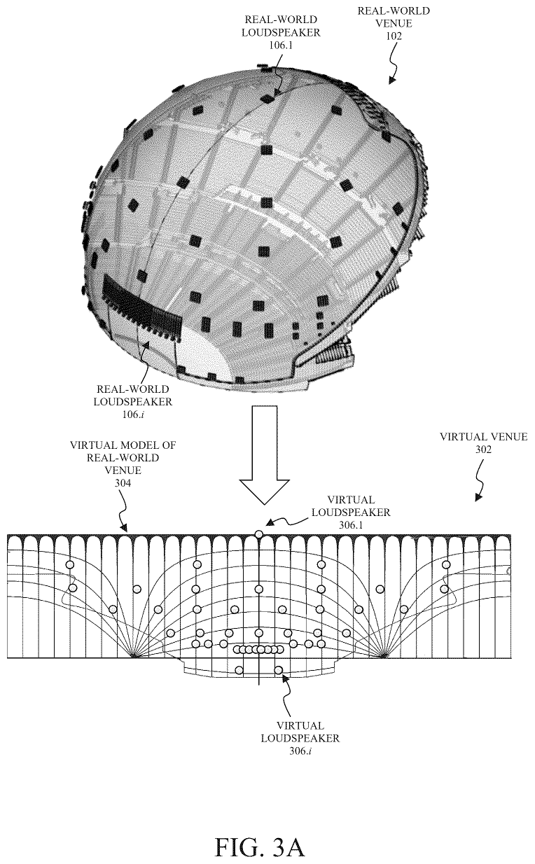

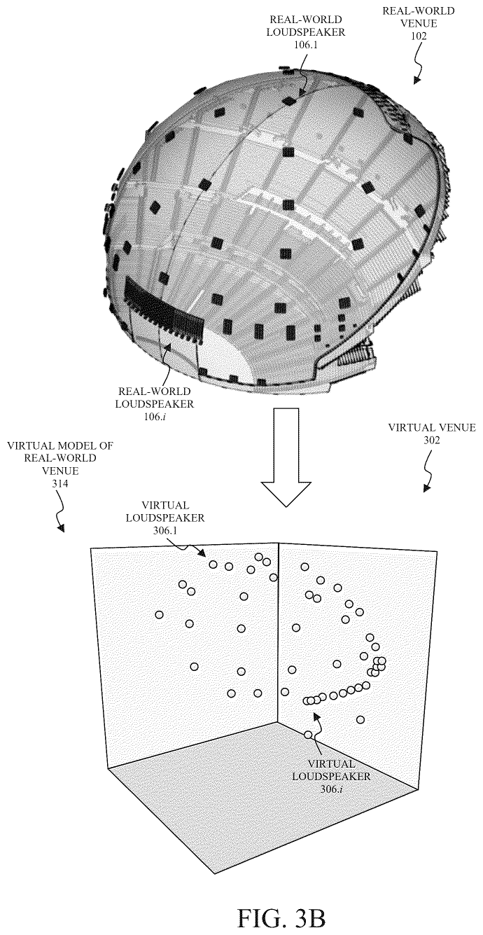

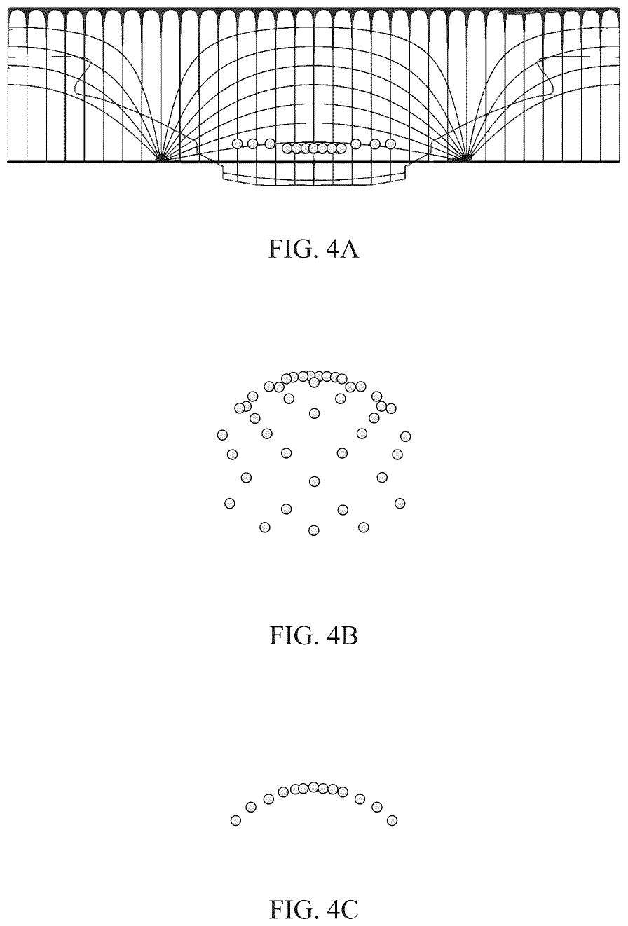

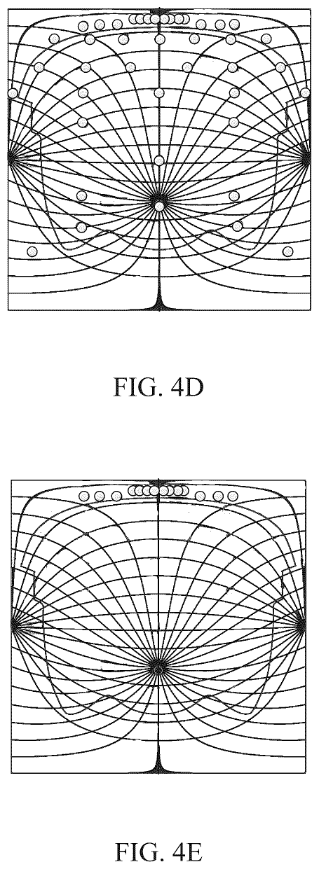

FIG. 3A and FIG. 3B graphically illustrate exemplary virtual models of an exemplary real-world venue that can be incorporated within the exemplary audio simulation system in accordance with some exemplary embodiments of the present disclosure. In the exemplary embodiments illustrated in FIG. 3A and FIG. 3B, the audio simulation workstation 104 can execute the audio mapping tool 108 and/or the audio monitoring tool 110, among others, as described herein to access a virtual venue 302 that incorporates a computer-generated model of the real-world venue 102 in the virtual environment. In some embodiments, the virtual venue 302 can include virtual loudspeakers 306.1 through 306.i that are associated with the real-world loudspeakers 106.1 through 106.i in the virtual environment. These virtual loudspeakers are illustrated as shaded circles within the virtual venue 302 in FIG. 3A and the virtual venue 312 in FIG. 3B. In some embodiments, the virtual venue 302 can include less virtual loudspeakers than the real-world loudspeakers 106.1 through 106.i within the real-world venue 102, for example, as illustrated in FIG. 4A, FIG. 4C, and FIG. 4E.

In some embodiments, the virtual venue 302 can be modeled to acoustically behave in accordance with one or more acoustical properties of the real-world venue 102, such as, without limitation, speed of sound, absorption, reflection, reverberation, transmission loss, diffraction, frequency response, impedance, resonance, and/or diffusion, among others, in the virtual environment. This advantageously allows audio professionals to evaluate various sounds, soundwaves, or the like propagating through the virtual venue 302 as described herein as if these sounds, soundwaves, or the like were propagating through the real-world venue 102 without being physically present at the real-world venue 102. In some embodiments, the virtual loudspeakers 306.1 through 306.i can be modelled in the virtual venue 302 to have substantially similar spatial arrangements with respect to one another as the real-world loudspeakers 106.1 through 106.i within the real-world venue 102 in the virtual environment. Alternatively, or in addition to, the virtual loudspeakers 306.1 through 306.i can be modelled in the virtual venue 302 to have substantially similar acoustical properties of the real-world loudspeakers 106.1 through 106.i, such as, without limitation, sensitivity, magnitude, phase, frequency, and/or directivity among others, in these embodiments.

As illustrated in FIG. 3A, the real-world venue 102 can be projected from three-dimensions in the real-world environment onto two-dimensions in the virtual environment to incorporate a virtual model of real-world venue 304 within the virtual venue 302. In some embodiments, these two-dimensional (2D) representations can include a latitude/longitude two-dimensional (2D) representation of the real-world venue 102 in the virtual environment as illustrated in FIG. 4A. However, other two-dimensional (2D) representations, such as, without limitation, top-down representations illustrated in FIG. 4B and FIG. 4C, fisheye representations illustrated in FIG. 4D and FIG. 4E, equirectangular representations, and/or cubemap representations, among others, of the real-world venue 102 in the virtual environment are possible without departing form the spirit and scope of the present disclosure. In some embodiments, the virtual venue 302 can incorporate two-dimensional (2D) spatial rendering within the virtual model of real-world venue 304 for purposes of directional audio panning, visibility mapping, and/or planar camera tracking, among others within the virtual environment. Alternatively, or in addition to, as illustrated in FIG. 3B, the real-world venue 102 can be projected from three-dimensions in the real-world environment onto three-dimensions in the virtual environment to incorporate a virtual model of real-world venue 314 within the virtual venue 302. In some embodiments, these three-dimensional (3D) representations can include polygonal mesh models, point cloud models, or voxel-based spatial constructs that define the geometry and structure of the real-world venue 102 in the virtual environment with varying levels of resolution and detail. In some embodiments, the virtual venue 302 can support volumetric rendering onto the virtual model of real-world venue 314 for purposes of accurate spatial audio reproduction, line-of-sight calculations, and/or virtual camera navigation, among others within the virtual environment. Depending on implementation, the virtual venue 302 can also incorporate metadata such as surface reflectivity, audience zones, stage areas, and sound obstruction zones, among others, to aid in rendering audio, video, and interactive content with enhanced realism and fidelity. In some implementations, the audio simulation workstation 104 can dynamically switch between, or combine, the virtual model of real-world venue 304 and the virtual model of real-world venue 314 depending on the capabilities of the rendering engine, device constraints, or user preferences. This flexibility allows the audio simulation workstation 104 to scale from lightweight two-dimensional (2D) visualizations to immersive three-dimensional (3D) simulations suited for augmented reality (AR), virtual reality (VR), and/or extended reality (XR) applications, among others.

### Exemplary Operations of the Exemplary Audio Simulation System

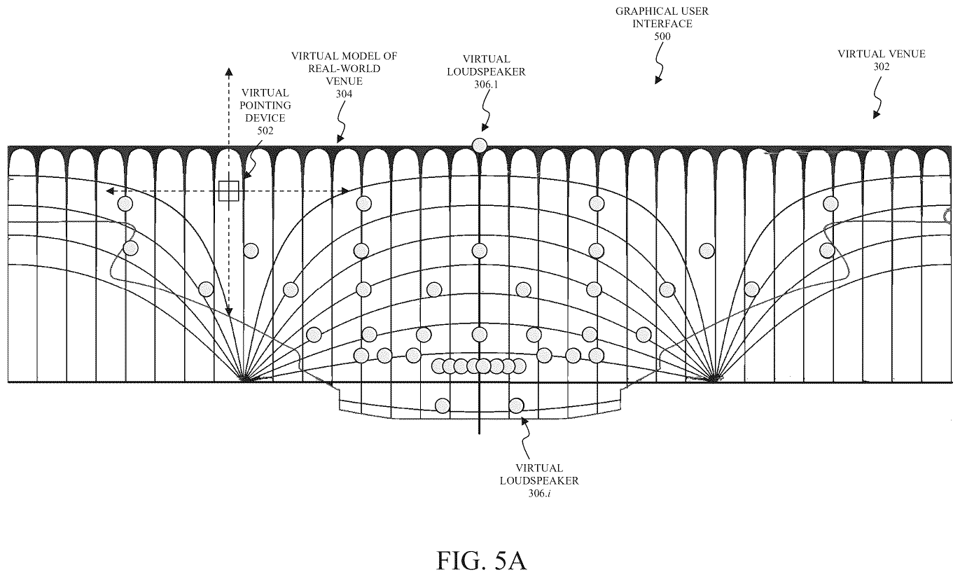

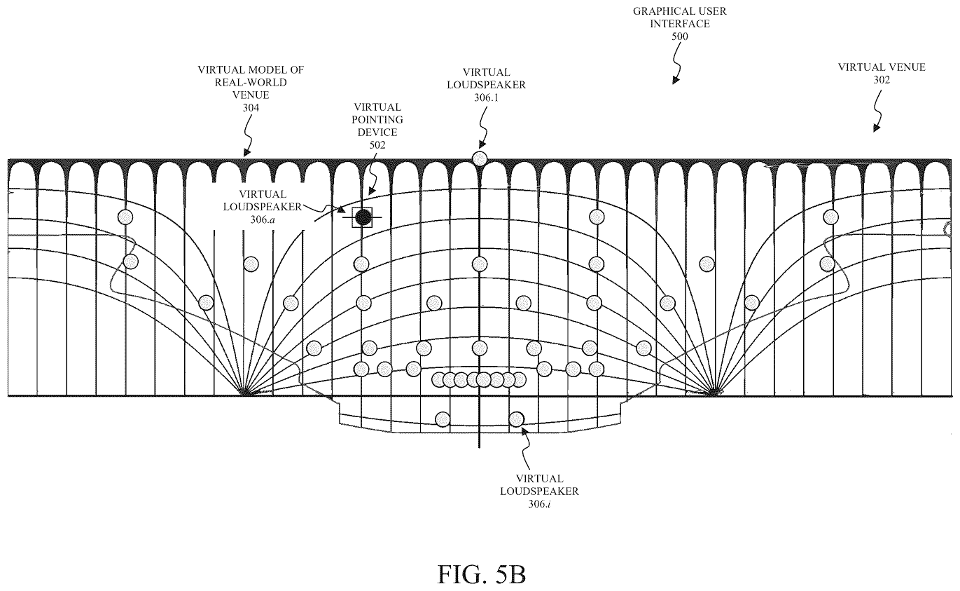

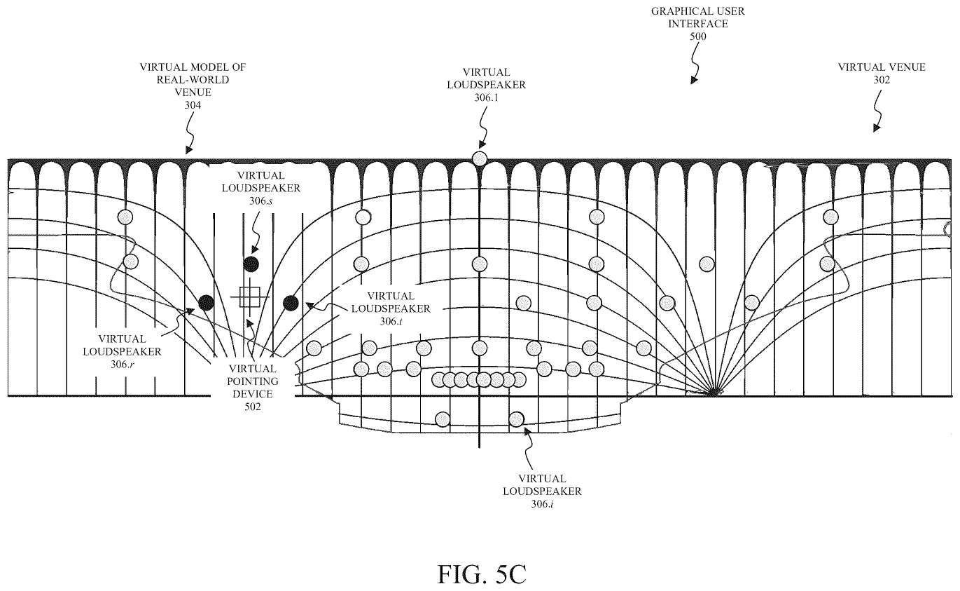

FIG. 5A through FIG. 5C graphically illustrate exemplary operations of the exemplary audio simulation system in accordance with some exemplary embodiments of the present disclosure. The following discussion is to describe a graphical user interface (GUI) 500 that can be utilized by one or more electronic, mechanical, and/or electro-mechanical devices, such as, without limitation, the audio simulation workstation 104, to assign, or map, the discrete audio input channels 152.1 through 152.n onto the composite audio output channels 154.1 through 154.i. In some embodiments, the GUI 500 enables flexible and remote control over the assignment, or mapping, of the discrete audio input channels 152.1 through 152.n onto the composite audio output channels 154.1 through 154.i allowing audio professionals to configure and manage audio routing from a centralized workstation or off-site location. Moreover, the graphical nature of the GUI 500 allows for intuitive, visual interaction to make it easier to understand and modify the assignment, or mapping, of the discrete audio input channels 152.1 through 152.n as compared to command-line or text-based configurations. The incorporation of the GUI 500 within the audio simulation workstation 104 allows audio professionals to implement spatially aware audio simulations to improve the realism and precision of sound placement in both virtual and real-world environments. It should be noted that the disclosure is not limited to this exemplary GUI. Rather, it will be apparent to those skilled the relevant art(s) that other operational GUIs are within the scope and spirit of the present disclosure. In some embodiments, audio professionals can interact with the GUI 500 to interface with the audio simulation workstation 104 executing the audio mapping tool 108 and/or the audio monitoring tool 110 to provide some examples to assign, or map, the discrete audio input channels 152.1 through 152.n onto the composite audio output channels 154.1 through 154.i.

As illustrated in FIG. 5A, the GUI 500 incorporates the virtual venue 302 having the virtual model of real-world venue 304 and the virtual loudspeakers 306.1 through 306.i. In the exemplary embodiment illustrated in FIG. 5A, the virtual model of real-world venue 304 represents a latitude/longitude two-dimensional (2D) representation of the real-world venue 102 in the virtual environment. However, those skilled in the relevant art(s) will recognize that the virtual model of real-world venue 304 can represent other two-dimensional (2D) representations and/or even other three-dimensional (3D) representations of the real-world venue 102 in the virtual environment. In the exemplary embodiment illustrated in FIG. 5A, the GUI 500 includes a virtual pointing device 502 to allow audio professionals to interact with the GUI 500 by positioning a virtual pointing device 502 within the virtual model of the real-world venue 304 to identify one or more corresponding virtual mapping locations, for example, one or more corresponding virtual mapping locations from among the virtual mapping locations 250.1 through 250.n, for each discrete audio input channel from among the discrete audio input channels 152.1 through 152.n. In some embodiments, the audio simulation workstation 104 can execute n-independent instances of the GUI 500 to assign, or map, each of the discrete audio input channels 152.1 through 152.n onto the composite audio output channels 154.1 through 154.i. In these embodiments, the audio simulation workstation 104 can present these n-independent instances of the GUI 500 as one or more windows that can be, for example moved, resized, minimized, and/or maximized, among others. In these embodiments, each of these n-independent instances of the GUI 500 can interface with one or more of the mapping tools 204 to assist the one or more of the mapping tools 204 to provide corresponding virtual mapping locations from among the virtual mapping locations 250.1 through 250.n. In some embodiments, these audio professionals can interact with the GUI 500 to identify the one or more corresponding virtual mapping locations. In these embodiments, these audio professionals can interact with the GUI 500 to identify the one or more corresponding virtual mapping locations during playback of the composite audio output channels 154.1 through 154.i by, for example, the audio monitoring tool 110 described herein. Although the virtual pointing device 502 is illustrated using a square icon in FIG. 5A through FIG. 5C, this is for exemplary purposes only. Those skilled in the relevant art(s) will recognize that the virtual pointing device 502 can be implemented using any suitable icon without departing from the spirit and scope of the present disclosure. In some embodiments, these audio professionals can move, or position, the virtual pointing device 502 on the virtual model of real-world venue 304 to identify the one or more corresponding virtual mapping locations. In these embodiments, these audio professionals can place, move, or position the virtual pointing device 502, for example, within a two-dimensional (2D) plane, such as, without limitation, an x-y plane of a Cartesian coordinate system, that aligns with the virtual model of real-world venue 304. In some embodiments, the GUI 500 can utilize a “point and click” interaction and/or “drag and drop” interaction, among others, to allow audio professionals to identify the one or more corresponding virtual mapping locations, for example, during playback of the composite audio output channels 154.1 through 154.i by, for example, the audio monitoring tool 110 described herein. Thereafter, the audio simulation workstation 104 can estimate the position, or location, of the virtual pointing device 502 within the virtual model of real-world venue 304 to identify the one or more corresponding virtual mapping locations. In some embodiments, the audio simulation workstation 104 can incorporate an Inversion of Control (IoC) mechanism to transfer control of the virtual pointing device 502 to one or more other electronic, mechanical, and/or electro-mechanical devices, such as, without limitation, an alphanumeric keyboard, a joystick, a keypad, pointing devices such as, without limitation, a mouse, trackball, touchpad, stylus, or graphics tablet, a scanner, a touchscreen incorporated into the display, audio input devices such as, without limitation, voice recognition systems or microphones, eye-gaze recognition, brainwave pattern recognition, and other types of input devices. This transfer of control allows these audio professionals to manipulate these other electronic, mechanical, and/or electro-mechanical devices to place, move, or position, the virtual pointing device 502 within the virtual venue 302 to identify the corresponding virtual mapping location.

As illustrated in FIG. 5B and FIG. 5C, the audio simulation workstation 104 executing the audio mapping tool 108 and/or the audio monitoring tool 110 to provide some examples can assign, or map, each discrete audio input channel from among the discrete audio input channels 152.1 through 152.n onto one or more of the composite audio output channels 154.1 through 154.i. In the exemplary embodiment illustrated in FIG. 5B and FIG. 5C, the audio simulation workstation 104 can access the one or more corresponding virtual mapping locations, namely, the positions, or locations, of the virtual pointing device 502 on the virtual model of real-world venue 304. After accessing the one or more corresponding virtual mapping locations, the audio simulation workstation 104 can identify one or more virtual loudspeakers from among the virtual loudspeakers 306.1 through 306.i that correspond to the one or more corresponding virtual mapping locations. For example, as illustrated in FIG. 5B, the audio simulation workstation 104 can identify a virtual loudspeaker 306.a from among the virtual loudspeakers 306.1 through 306.i that is closest to the one or more corresponding virtual mapping locations. In this example, the audio simulation workstation 104 can proactively place, move, or position the virtual pointing device 502 onto the virtual loudspeaker 306.a as illustrated in FIG. 5B in a “snap” mode of operation. In another example, as illustrated in FIG. 5C, the audio simulation workstation 104 can identify a virtual loudspeaker 306.r, a virtual loudspeaker 306.s and a virtual loudspeaker 306.t from among the virtual loudspeakers 306.1 through 306.i that are closest to the one or more corresponding virtual mapping locations. In this other example, the virtual loudspeaker 306.r, the virtual loudspeaker 306.s and the virtual loudspeaker 306.t are configured and arranged to form an imaginary virtual loudspeaker within the virtual venue 302 at the virtual pointing device 502 in a “free” mode of operation. In some embodiments, the audio simulation workstation 104 can emphasize, for example, highlight, the one or more virtual loudspeakers that have been identified on the GUI 500. After identifying the one or more virtual loudspeakers, the audio simulation workstation 104 can assign, or map, one or more discrete audio input channels from among the discrete audio input channels 152.1 through 152.n onto one or more composite audio output channels from among the composite audio output channels 154.1 through 154.i that are associated with the one or more virtual loudspeakers.

Although the foregoing description of FIG. 5A through FIG. 5C has been presented in the context of the virtual model of the real-world venue 304, those skilled in the relevant art(s) will recognize that other graphical user interfaces may likewise be employed that incorporate the virtual model of real-world venue 314 without departing from the spirit and scope of the present disclosure. In some embodiments, these graphical user interfaces may include corresponding virtual pointing devices operable to select one or more virtual mapping locations within the virtual venue 302 by clicking, dragging, or otherwise positioning these virtual pointing devices within the virtual model of the real-world venue 314 in a substantially similar manner as described herein. In these embodiments, the audio simulation workstation 104 can access these virtual mapping locations to assign, or map, the discrete audio input channels 152.1 through 152.n onto the composite audio output channels 154.1 through 154.i in a substantially similar manner as described herein.

Another Exemplary Virtual Model of the Exemplary Real-World Venue that can be Incorporated within the Exemplary Audio Simulation System

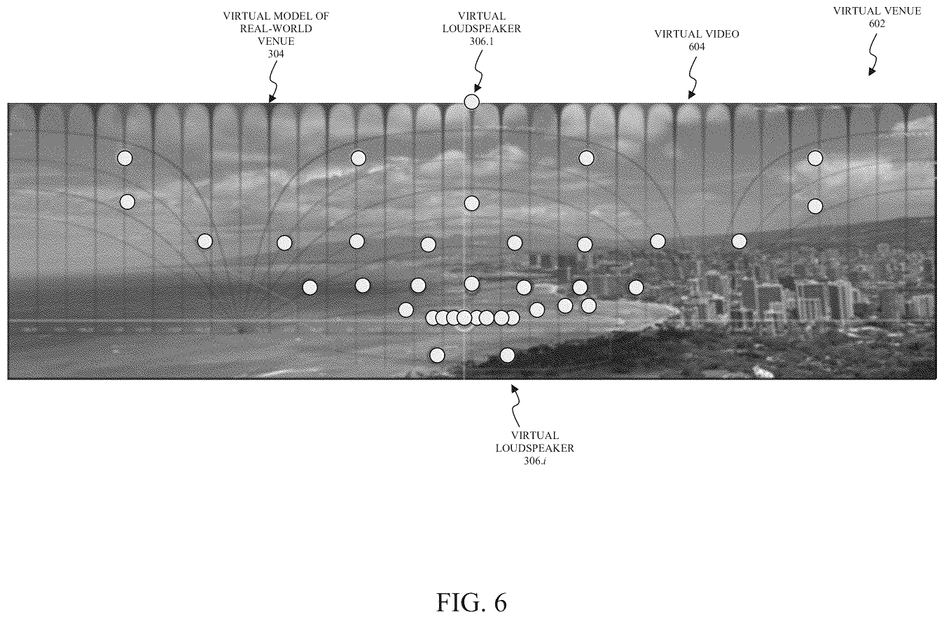

FIG. 6 graphically illustrates another exemplary virtual model of the exemplary real-world venue that can be incorporated within the exemplary audio simulation system in accordance with some exemplary embodiments of the present disclosure. In the exemplary embodiments illustrated in FIG. 6, the audio simulation workstation 104 can execute the audio mapping tool 108 and/or the audio monitoring tool 110, among others, as described herein to access a virtual venue 602 that incorporates a computer-generated model of the real-world venue 102 in the virtual environment. The virtual venue 602 offers a range of technical and operational advantages that enhance the design, testing, and execution of audio-visual experiences within the virtual venue 602. As illustrated in FIG. 6, the virtual venue 602 integrates a video, or an image, onto the virtual model of the real-world venue 304 to enable synchronized playback of both composite audio output channels and the video, or the image. This synchronized playback allows audio professionals to preview an event as it would be experienced at the real-world venue without requiring physical presence. Such functionality supports remote collaboration, planning, and iterative refinement of audio and video elements. By simulating the real-world playback of the video, or the image, the audio simulation workstation 104 can ensure that design intentions are faithfully translated into final presentations. Additionally, the ability to conduct comprehensive evaluations of complex or acoustically challenging venues in the virtual environment streamlines project workflows and reduces the need for costly on-site adjustments. In the exemplary embodiment illustrated in FIG. 6, the virtual venue 602 is shares many substantially similar features as the virtual venue 302 as described herein. As such, only differences between the virtual venue 302 and the virtual venue 602 are to be described in further detail below. Although the description of FIG. 6 is to be presented in the context of the virtual model of the real-world venue 304, those skilled in the relevant art(s) will recognize that similar video content, or images, may likewise be overlaid onto the virtual model of the real-world venue 314 within the virtual environment in a substantially similar manner as described herein without departing from the spirit and scope of the present disclosure.

As illustrated in FIG. 6, the virtual venue 602 can include a virtual video 604, or a simply a virtual image (not shown in FIG. 6), that is overlaid onto the virtual model of real-world venue 304 in the virtual environment. In some embodiments, the virtual video 604 represents a computer-generated representation of the actual video that is associated with the event in the virtual environment. As illustrated in FIG. 6, the virtual model of real-world venue 304 represents a latitude/longitude two-dimensional (2D) representation of the real-world venue 102 in the virtual environment that is substantially similar to a camera lens that captured the actual video that is associated with the event. In some embodiments, this likeness between the virtual model of real-world venue 304 and the camera lens that captured the actual video can advantageously minimize barrel distortion, pincushion distortion, fisheye effect, and/or chromatic aberration, among others as the virtual video 604 is being played back on the virtual venue 302 in the virtual environment. As a result, the virtual video 604 more accurately reflects the expected real-world presentation of the actual video in the real-world venue 102.

In the exemplary embodiment illustrated in FIG. 6, the audio simulation workstation 104 can playback the composite audio output channels 154.1 through 154.i and/or the virtual video 604. In some embodiments, the audio simulation workstation 104 can playback of the composite audio output channels 154.1 through 154.i and/or the virtual video 604 in synchronicity. In these embodiments, the audio simulation workstation 104 can synchronize playback of the composite audio output channels 154.1 through 154.i with the virtual video 604 based on timecode alignment, metadata tagging, and/or audio-visual synchronization algorithms, among others, to ensure frame-accurate timing between the auditory and visual experiences. This synchronous playback capability enables audio professionals to preview the event on the virtual venue 602 in the virtual environment as it would be played back on the real-world venue 102 without being physically present at the real-world venue 102. These audio professionals can assess the timing, spatial placement, intensity, and quality of the composite audio output channels 154.1 through 154.i in relation to on-screen events, speaker movements, or other visual cues within the virtual video 604. The ability to perform this type of evaluation remotely and in advance of an actual deployment eliminates the need for on-site rehearsals or costly staging sessions, thereby reducing labor, travel, and equipment costs. Furthermore, the synchronized playback functionality allows these audio professionals to interface with the audio simulation workstation 104 to make iterative adjustments in real-time, or near-real-time, to the composite audio output channels 154.1 through 154.i and/or the virtual video 604. In some embodiments, the audio simulation workstation 104 can further enable features such as pause, scrub, loop, and zoom functionalities during playback to facilitate detailed analysis and fine-tuning of the composite audio output channels 154.1 through 154.i and the virtual video 604. In these embodiments, the audio simulation workstation 104 can record, or visually overlay, annotations or mapping updates onto the virtual model of real-world venue 304. In this manner, the audio simulation workstation 104 provides a robust and immersive simulation environment for previewing and optimizing complex event productions prior to deployment at the real-world venue 102.

### Exemplary Audio Monitoring Tool

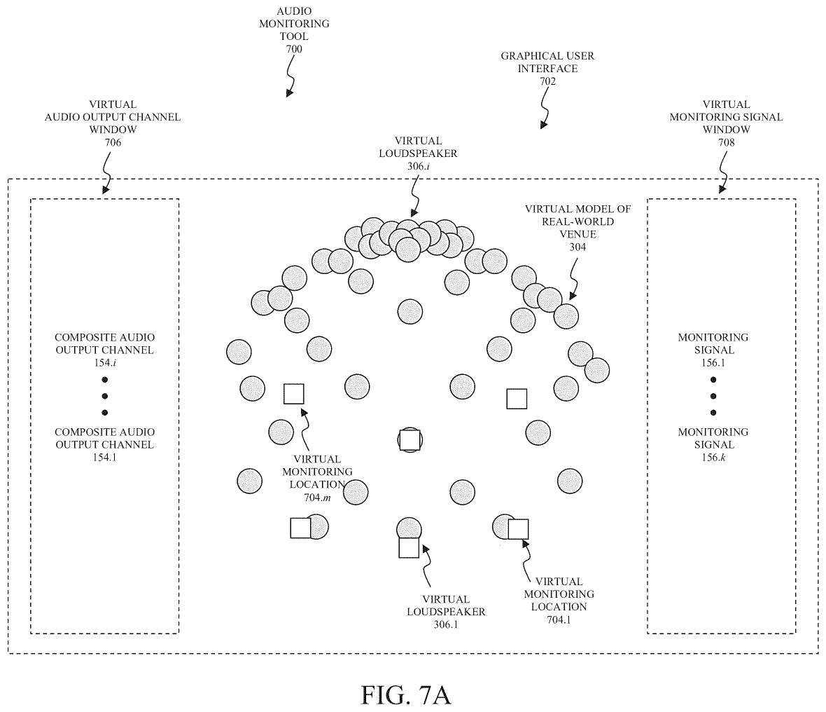

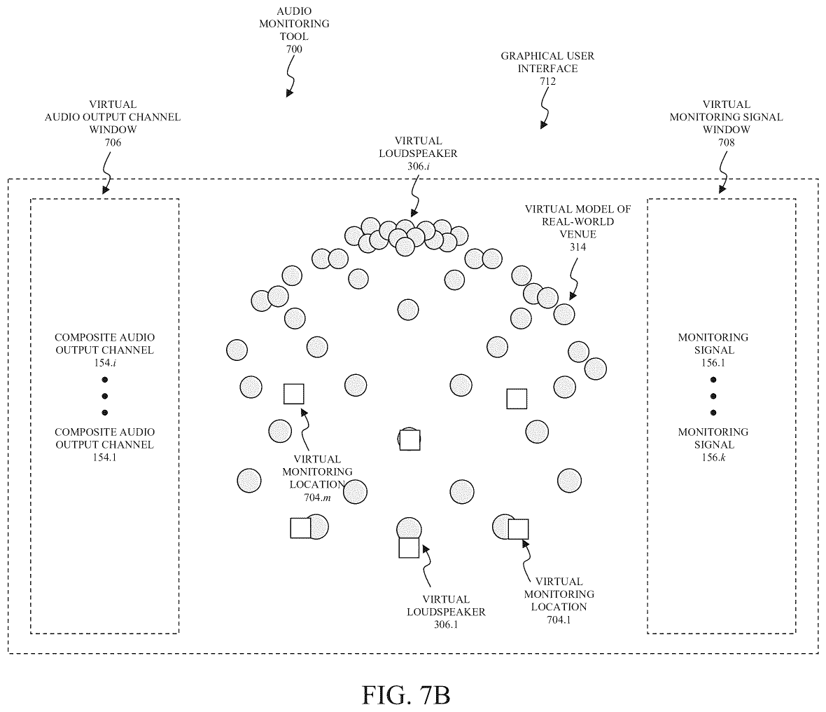

FIG. 7A and FIG. 7B graphically illustrate exemplary operations of an exemplary audio monitoring tool that can be incorporated within the exemplary audio simulation system in accordance with some exemplary embodiments of the present disclosure. As described herein, an audio monitoring tool 700 can playback the composite audio output channels 154.1 through 154.i. As illustrated in FIG. 7A and FIG. 7B, the audio monitoring tool 700 can monitor the composite audio output channels 154.1 through 154.i to assess the fidelity of the audio, for example, accuracy and/or quality, to be played back by the real-world venue 102, which helps to identify and resolve potential issues early in the design process. Moreover, the audio monitoring tool 700 provides a vital feedback loop in the simulation-driven design process, allowing for real-time refinement of audio configurations, including loudspeaker placement and channel mapping. Ultimately, these capabilities lead to more informed design decisions and a higher-quality audio experience when deployed in the real-world venue 102. In some embodiments, the audio monitoring tool 700 can be executed on one or more suitable electrical, mechanical, and/or electro-mechanical devices, such as, without limitation, the audio simulation workstation 104. In some embodiments, these suitable electrical, mechanical, and/or electro-mechanical devices can be standalone devices to allow audio professionals to monitor the composite audio output channels 154.1 through 154.i without these audio professionals being physically present at the real-world venue. In these embodiments, this remote capability provides significant flexibility, reduces travel-related costs, and enables more efficient workflows, particularly during pre-production or rehearsal stages.

In the exemplary embodiments illustrated in FIG. 7A and FIG. 7B, the audio monitoring tool 700 can incorporate a graphical user interface (GUI) 702 and a GUI 712, respectively, that can be utilized by one or more electronic, mechanical, and/or electro-mechanical devices, such as, without limitation, the audio simulation workstation 104, to dynamically monitor the composite audio output channels 154.1 through 154.i. In some embodiments, audio professionals can interact with the GUI 702 and/or the GUI 712 to interface with the audio monitoring tool 700 to assess the fidelity of the composite audio output channels 154.1 through 154.i within the virtual environment. This assessment emulates the manner in which the audio would be reproduced within the real-world venue 102, thereby enabling these audio professionals to evaluate the composite audio output channels 154.1 through 154.i without requiring physical presence at the real-world venue 102. In some embodiments, the GUI 702 and/or the GUI 712 enable flexible and remote access to the monitoring and evaluation of the composite audio output channels 154.1 through 154.i to allow audio professionals to assess playback fidelity from either a centralized workstation or an off-site location. In these embodiments, the GUI 702 and/or the GUI 712 facilitate real-time, or near real-time, observation of key audio characteristics of the composite audio output channels 154.1 through 154.i, such as, without limitation, sensitivity, magnitude, phase, frequency, and/or directivity, among others, to enhance the ability to detect and address potential issues early in the design or rehearsal phases. The visual nature of the GUI 702 and/or the GUI 712 provide for an intuitive platform for understanding the behavior of the composite audio output channels 154.1 through 154.i within the simulation environment, particularly in relation to how they will perform when deployed in the real-world venue 102. Through integration with the audio simulation workstation 104 or other suitable standalone devices, the GUI 702 and/or the GUI 712 support dynamic, spatially aware analysis of the composite audio output channels 154.1 through 154.i, enabling audio professionals to fine-tune configurations such as loudspeaker placement, phase alignment, and channel blending in real time, or near real-time. As a result, audio professionals can make decisions that are more informed and produce a more immersive and high-fidelity audio experience for real-world deployment. It will be appreciated by those skilled in the relevant art(s) that the GUI 702 and the GUI 712 are merely one exemplary implementation, and that other functional GUIs may likewise be employed to perform similar monitoring tasks without departing from the scope or spirit of the present disclosure. In some implementations, the audio monitoring tool 700 can dynamically switch between, or combine, the GUI 702 and the GUI 712 depending on the capabilities of the rendering engine, device constraints, or user preferences. This flexibility allows the audio monitoring tool 700 to scale from lightweight two-dimensional (2D) visualizations to immersive three-dimensional (3D) simulations suited for augmented reality (AR), virtual reality (VR), and/or extended reality (XR) applications, among others.

As illustrated in FIG. 7A, the GUI 702 incorporates the virtual venue 302 having the virtual model of real-world venue 304 and the virtual loudspeakers 306.1 through 306.i. In the exemplary embodiment illustrated in FIG. 7A, the virtual model of real-world venue 304 represents a top-down two-dimensional (2D) representation of the real-world venue 102 in the virtual environment. However, those skilled in the relevant art(s) will recognize that the virtual model of real-world venue 304 can represent other two-dimensional (2D) representations and/or even other three-dimensional (3D) representations of the real-world venue 102 in the virtual environment. And as illustrated in FIG. 7B, the GUI 702 incorporates the virtual venue 302 having the virtual model of real-world venue 314 and the virtual loudspeakers 306.1 through 306.i. In the exemplary embodiment illustrated in FIG. 7B, the virtual model of real-world venue 304 represents a top-down three-dimensional (3D) representation of the real-world venue 102 in the virtual environment. However, those skilled in the relevant art(s) will recognize that the virtual model of real-world venue 314 can represent other two-dimensional (2D) representations and/or even other three-dimensional (3D) representations of the real-world venue 102 in the virtual environment.

In the exemplary embodiment illustrated in FIG. 7A and the FIG. 7B, the GUI 702 and the GUI 712 include one or more virtual monitoring locations 704.1 through 704.m (shown as rectangles in FIG. 7A and the FIG. 7B) that are distributed throughout the virtual model of real-world venue 304 and the virtual model of real-world venue 314, respectively. In some embodiments, each of the virtual monitoring locations 704.1 through 704.m can correspond to a specific physical location within the real-world venue 102, such as, without limitation, individual audience seating areas, VIP sections, balconies, control booths, or other acoustically relevant zones, among others. The virtual monitoring locations 704.1 through 704.m allow audio professionals to assess and compare the perceived audio quality, fidelity, and spatial characteristics as they would be experienced in a real-world venue, such as, without limitation, the real-world venue 102.

In the exemplary embodiments illustrated in FIG. 7A and FIG. 7B, the audio monitoring tool 700 can simulate the playback of the composite audio output channels 154.1 through 154.i through the virtual loudspeakers 306.1 through 306.i to one or more virtual monitoring locations from among the virtual monitoring locations 704.1 through 704.m. In some embodiments, audio professionals can interact with the GUI 702 and/or the GUI 712 to select the one or more virtual monitoring locations to simulate the playback of the composite audio output channels 154.1 through 154.i through the virtual loudspeakers 306.1 through 306.i to the one or more virtual monitoring locations. As part of this simulating, the audio monitoring tool 700 can generate one or more virtual soundwaves in the virtual environment that correspond to the composite audio output channels 154.1 through 154.i. Thereafter, the audio monitoring tool 700 can simulate the propagation of these virtual soundwaves through the virtual loudspeakers to the one or more virtual monitoring locations. In some embodiments, the audio monitoring tool 700 can perform one or more simulations, such as, without limitation, a finite difference time domain (FDTD) simulation, a finite element method (FEM) simulation, a ray tracing simulation, direct sound impulse response simulation, diffuse field simulation, and/or an image method simulation, among others, to mimic how these virtual soundwaves propagate through and interact with the virtual model of real-world venue 304. Generally, these simulations use various mathematical models and computational techniques to mimic how these virtual soundwaves propagate through and interact with the virtual model of real-world venue 304. These mathematical models and computational techniques effectively discretize the virtual model of real-world venue 304 into a grid or mesh, solve various wave equations, for example, one-dimensional wave equations, two-dimensional (2D) wave equations, three-dimensional (3D) wave equations, Hemholtz equations, Klein-Gordon equations, Schrodinger equations, and/or Maxwell's equations, among others, iteratively over time, and update sound pressure and/or particle velocity fields according to the wave equations. In some embodiments, this simulation of the propagation of these virtual soundwaves can consider one or more acoustical properties of the real-world loudspeakers 106.1 through 106.i, such as, without limitation, sensitivity, magnitude, phase, frequency, and/or directivity, among others, and/or one or more acoustical properties of the real-world venue 102, such as, without limitation, speed of sound, absorption, reflection, reverberation, transmission loss, diffraction, frequency response, impedance, resonance, and/or diffusion, among others.

In some embodiments, the audio monitoring tool 700 can quantitatively estimate one or more acoustical characteristics of the one or more virtual soundwaves at the one or more virtual monitoring locations. These acoustical characteristics may include, without limitation, can include, without limitation, time delay, sound pressure level (SPL), sound power, direct sound impulse response, diffuse field response, early reflections, reverberation time, clarity indices, interaural cross-correlation (IACC), spatial impression metrics, frequency response, phase response, impulse-to-noise ratio (INR), total harmonic distortion (THD), intermodulation distortion (IMD), direct-to-reverberant ratio (D/R ratio), signal-to-noise ratio (SNR), crest factor, sound coverage uniformity, speech transmission index (STI), modulation transfer function (MTF), echo density, binaural parameters such as interaural time difference (ITD), head-related transfer function (HRTF), and binaural loudness level, perceived loudness, perceived clarity, listener envelopment (LEV), localization accuracy, and/or psychoacoustic descriptors such as warmth, brightness, and harshness, among others. In some embodiments, the audio monitoring tool 700 can evaluate the acoustical interactions between the one or more virtual soundwaves assessing phenomena such as constructive and destructive interference, comb filtering effects, and phase coherence at the one or more virtual monitoring locations. These estimations can inform iterative refinements of audio system configurations, including loudspeaker placement, equalization, delay settings, and output channel routing, ultimately contributing to an optimized and immersive auditory experience within the real-world venue 102. In some embodiments, the audio monitoring tool 700 can render the one or more monitoring output signals 156.1 through 156.k corresponding to the one or more virtual soundwaves as perceived at the one or more virtual monitoring locations to enable playback of the composite audio output channels 154.1 through 154.i through headphones or loudspeakers. In these embodiments, the audio monitoring tool 700 can generate the one or more monitoring output signals 156.1 through 156.k to exhibit the one or more acoustical characteristics of the one or more virtual soundwaves at the one or more virtual monitoring locations. This beneficially allows audio professionals to listen to, analyze, and refine the assignment, or mapping, of the discrete audio input channels 152.1 through 152.n onto composite audio output channels 154.1 through 154.i at the one or more virtual monitoring locations 704.1 through 704.m. In some embodiments, the audio monitoring tool 700 can transcode the one or more monitoring output signals 156.1 through 156.k to arbitrary loudspeaker arrangements, custom or following loudspeaker layout standards as well as binauralized for headphone playback while keeping the temporal, spectral and spatial properties of the one or more virtual soundwaves as perceived at the one or more virtual monitoring locations intact. In these embodiments, the audio monitoring tool 700 can transcode the one or more monitoring output signals 156.1 through 156.k in accordance with a surround sound standard, such as, without limitation, a version of Dolby Digital, a version of Digital Theater Systems (DTS), a version of Dolby TrueHD, a version of DTS-HD Master Audio, a version of Dolby Atmos, a version of DTS: X, a version of Auro-3D, a version of Sony 360 Reality Audio, and/or a version of IMAX Enhanced, among others. In these embodiments, the audio monitoring tool 700 can incorporate a head tracking device to further increase realism of the spatial representation. Generally, the one or more monitoring output signals 156.1 through 156.k beneficially allow audio professionals to physically hear the composite audio output channels 154.1 through 154.i. at the one or more virtual monitoring locations to evaluate the composite audio output channels 154.1 through 154.i. as perceived at specific spatial locations associated with the one or more virtual monitoring locations 704.1 through 704.m in the real-world venue. As such, these audio professionals can evaluate the composite audio output channels 154.1 through 154.i as if the composite audio output channels 154.1 through 154.i were being played back at the real-world venue 102 without these audio professionals being physically present at the real-world venue 102. These capabilities enable remote auditory validation of system performance, support pre-venue calibration workflows, and promote accurate decision-making during the design and tuning stages without requiring physical presence at the real-world venue 102. As a result, these embodiments contribute to significant time and cost savings while enhancing the overall effectiveness and precision of audio system deployment.

As illustrated in FIG. 7A and FIG. 7B, the audio monitoring tool 700 can measure, monitor, and/or meter one or more characteristics, parameters, and/or attributes, collectively referred to as characteristics for simplicity, of the composite audio output channels 154.1 through 154.i and/or the one or more monitoring output signals 156.1 through 156.k. In these embodiments, the characteristics can include, without limitation, time delay, sound pressure level (SPL), sound power, direct sound impulse response, diffuse field response, early reflections, reverberation time, clarity indices, interaural cross-correlation (IACC), spatial impression metrics, frequency response, phase response, impulse-to-noise ratio (INR), total harmonic distortion (THD), intermodulation distortion (IMD), direct-to-reverberant ratio (D/R ratio), signal-to-noise ratio (SNR), crest factor, sound coverage uniformity, speech transmission index (STI), modulation transfer function (MTF), echo density, binaural parameters such as interaural time difference (ITD), head-related transfer function (HRTF), and binaural loudness level, perceived loudness, perceived clarity, listener envelopment (LEV), localization accuracy, and/or psychoacoustic descriptors such as warmth, brightness, and harshness, among others.

In some embodiments, the audio monitoring tool 700 can emphasize real-time, visually rich feedback and interactivity to facilitate sound quality assurance and spatial audio optimization in the real-world venue 102. In these embodiments, the GUI 702 and the GUI 712 can include a virtual audio output channel window 706 for monitoring one or more characteristics for one or more of the composite audio output channels 154.1 through 154.i and a virtual monitoring signal window 708 for monitoring one or more characteristics for the one or more monitoring output signals 156.1 through 156.k. In some embodiments, the virtual audio output channel window 706 and/or the virtual monitoring signal window 708 can include one or more audio meters for visualizing the one or more characteristics for one or more of the composite audio output channels 154.1 through 154.i and the one or more characteristics for the one or more monitoring output signals 156.1 through 156.k, respectively. In these embodiments, the one or more audio meters can include one or more simple audio meters, such as, without limitation, volume unit (VU) meters, peak meters, Root Mean Square (RMS) meters, Loudness Units Full Scale (LUFS) meters, spectral meters, phase meters, and/or loudness meters, among others. Alternatively, or in addition to, the one or more audio meters can include one or more specialized audio meters, such as, without limitation, true peak meters for inter-sample peak detection, correlation meters for stereo phase relationship visualization, spectrogram meters for time-frequency analysis, third-octave band meters for standardized frequency band monitoring, K-weighted loudness meters, loudness range (LRA) meters for dynamic range assessment, phase vector scopes for stereo imaging, real-time analyzers (RTA) for frequency spectrum monitoring, distortion and noise meters for fidelity assurance, multi-channel meters for surround sound formats, and latency meters for synchronization evaluation. In some embodiments, the audio monitoring tool 700 can incorporate adjustable peak hold and integration time controls to tailor responsiveness of the one or more audio meters for precise transient or averaged level monitoring, as well as range and gain adjustment, threshold setting, hold time control, customizable ballistics for rise and fall times, weighting filters, channel grouping and linking, peak versus RMS mode switching, logging and history functions, color-coded level indicators to highlight safe, caution, and clipping zones, selectable linear or logarithmic scales with auto-scaling or manual scaling options, peak overshoot compensation, and/or integration window adjustment, among others, to provide comprehensive and flexible audio measurement and visualization capabilities.

In some embodiments, these audio meters can be characterized as advantageously providing near immediate visual feedback of the composite audio output channels 154.1 through 154.i and/or the one or more monitoring output signals 156.1 through 156.k to assist audio professionals in quickly identifying potential anomalies or imbalances, monitoring audio dynamics, evaluating spectral content, and confirming spatial coherence. These real-time visualizations support efficient audio system calibration, verification, and quality control during design, simulation, and pre-production phases. In some embodiments, the one or more audio meters may also be interactively linked to specific monitoring locations, output channels, or simulation parameters, enabling intuitive navigation and manipulation. Collectively, these features enhance user situational awareness and control, streamline workflow, and contribute to delivering a consistent and high-fidelity auditory experience within the real-world venue 102.

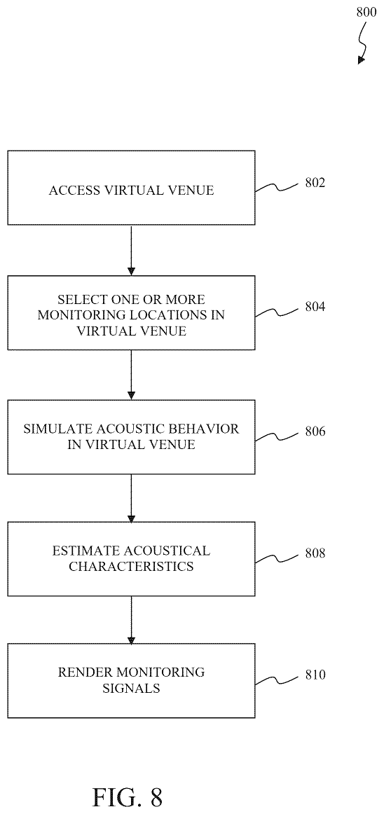

FIG. 8 illustrates a flowchart for the exemplary audio monitoring tool in accordance with various embodiments. The disclosure is not limited to this operational description. Rather, it will be apparent to ordinary persons skilled in the relevant art(s) that other operational control flows are within the scope and spirit of the present disclosure. The following discussion describes an exemplary operational control flow 800 for monitoring the composite audio output channels 154.1 through 154.i to assess the fidelity of the audio, for example, accuracy and/or quality, to be played back by the real-world venue 102. In the exemplary embodiment illustrated in FIG. 8, the operational control flow 800 can be performed by the exemplary audio monitoring tool, such as, without limitation, the audio monitoring tool 100 and/or the audio monitoring tool 700, executing on an exemplary audio simulation workstation, such as, without limitation, the audio simulation workstation 104 to monitor the composite audio output channels 154.1 through 154.i at one or more virtual locations within a virtual venue, such as the virtual venue 302 that incorporates a computer-generated model of a real-world venue, such as the real world venue 102, in a virtual environment. The operational control flow 800 beneficially allows audio professionals to physically hear the one or more composite audio output channels 154.1 through 154.i at the one or more virtual locations soundwaves evaluate the composite audio output channels 154.1 through 154.i. As such, these audio professionals can evaluate the composite audio output channels 154.1 through 154.i as if the composite audio output channels 154.1 through 154.i were being played back at the real-world venue 102 without these audio professionals being physically present at the real-world venue 102. In some embodiments, these tools allow audio content for an event to be developed remotely, without the need to be physically present in the real-world venue 102. For example, these audio professionals can create show-specific content entirely off-site from the real-world venue 102, using the virtual monitoring capabilities to simulate how the content will be perceived in the real-world venue 102. As another example, a these audio professionals can perform virtual sound checks with performers from a remote location, enabling refinement of the audio content prior to arriving at the real-world venue 102. This significantly reduces the time and resources required for on-site rehearsals and facilitates a more efficient and streamlined production workflow.

At operation 802, the operational control flow 800 accesses the virtual model. In some embodiments, the virtual model includes a virtual model of the real-world venue, such as the virtual model of real-world venue 304 and/or the virtual model of real-world venue 314 that replicates the geometry and acoustics of the real-world venue in two or three-dimensions. In these embodiments, the operational control flow 800 can derive the virtual model of the real-world venue from photogrammetry, Light Detection and Ranging (LiDAR) scans, architectural Computer-Aided Design (CAD) data, and/or other spatial mapping techniques, among others, that preserve the physical dimensions, material characteristics, and/or acoustic profiles, among others, of the real-world venue. In some embodiments, the virtual model of the real-world venue provides the structural framework that includes the one or more virtual locations for evaluating the composite audio output channels 154.1 through 154.i. In these embodiments, the virtual model allows audio professionals to perform monitoring and/or analysis tasks, among others, remotely without needing to be physically present at the real-world venue.

At operation 804, the operational control flow 800 selects the one or more virtual monitoring locations within the virtual model of the real-world venue. The one or more virtual monitoring locations can represent specific audience seating areas, mixing positions, stage zones, or other acoustically relevant points throughout the venue. In some embodiments, the operational control flow 800 can incorporate the GUI 702 and/or GUI 712 to allow audio professionals to interactively select the one or more virtual monitoring locations within the virtual model of the real-world venue. These virtual monitoring locations enable spatially aware analysis and refinement of the audio configuration, including channel mapping, timing, and effects processing, without needing to be physically present at the real-world venue.

At operation 806, the operational control flow 800 simulates the acoustical behavior of the composite audio output channels 154.1 through 154.i at the one or more virtual monitoring locations. As part of this simulating, the operational control flow 800 can simulate the one or more virtual soundwaves through one or more virtual loudspeakers incorporated within the virtual model that correspond to the composite audio output channels 154.1 through 154.i to the one or more virtual monitoring locations. In these embodiments, the operational control flow 800 simulates the acoustic propagation and spatial characteristics of the one or more virtual soundwaves as they would be perceived from the one or more virtual monitoring locations. In these embodiments, the operational control flow 800 can perform one or more simulations, such as, without limitation, a finite difference time domain (FDTD) simulation, a finite element method (FEM) simulation, a ray tracing simulation, direct sound impulse response simulation, diffuse field simulation, and/or an image method simulation, among others, to mimic how these virtual soundwaves propagate through and interact with the virtual model of real-world venue. Generally, these simulations use various mathematical models and computational techniques to mimic how these virtual soundwaves propagate through and interact with the virtual model of real-world venue. These mathematical models and computational techniques effectively discretize the virtual model of real-world venue into a grid or mesh, solve various wave equations, for example, one-dimensional wave equations, two-dimensional (2D) wave equations, three-dimensional (3D) wave equations, Hemholtz equations, Klein-Gordon equations, Schrodinger equations, and/or Maxwell's equations, among others, iteratively over time, and update sound pressure and/or particle velocity fields according to the wave equations. In some embodiments, this simulation of the propagation of these virtual soundwaves can consider one or more acoustical properties of one or more real-world loudspeakers incorporated within the real-world venue, such as, without limitation, sensitivity, magnitude, phase, frequency, and/or directivity, among others, and/or one or more acoustical properties of the real-world venue, such as, without limitation, speed of sound, absorption, reflection, reverberation, transmission loss, diffraction, frequency response, impedance, resonance, and/or diffusion, among others.

At operation 808, the operational control flow 800 can quantitatively estimate one or more acoustical characteristics of the composite audio output channels 154.1 through 154.i at the one or more virtual monitoring locations. In some embodiments, the operational control flow 800 can quantitatively estimate one or more acoustical characteristics of the one or more virtual soundwaves from operation 806 at the one or more virtual monitoring locations. These acoustical characteristics can include, without limitation, time delay, sound pressure level (SPL), sound power, direct sound impulse response, diffuse field response, early reflections, reverberation time, clarity indices, interaural cross-correlation (IACC), spatial impression metrics, frequency response, phase response, impulse-to-noise ratio (INR), total harmonic distortion (THD), intermodulation distortion (IMD), direct-to-reverberant ratio (D/R ratio), signal-to-noise ratio (SNR), crest factor, sound coverage uniformity, speech transmission index (STI), modulation transfer function (MTF), echo density, binaural parameters such as interaural time difference (ITD), head-related transfer function (HRTF), and binaural loudness level, perceived loudness, perceived clarity, listener envelopment (LEV), localization accuracy, and/or psychoacoustic descriptors such as warmth, brightness, and harshness, among others. In some embodiments, the operational control flow 800 can evaluate the acoustical interactions between the one or more virtual soundwaves from operation 806 assessing phenomena such as constructive and destructive interference, comb filtering effects, and phase coherence at the one or more virtual monitoring locations. These estimations can inform iterative refinements of audio system configurations, including loudspeaker placement, equalization, delay settings, and output channel routing, ultimately contributing to an optimized and immersive auditory experience within the real-world venue.

At operation 810, the operational control flow 800 can render one or more monitoring output signals, such as the one or more monitoring output signals 156.1 through 156.k, corresponding to the one or more virtual soundwaves as perceived at the one or more virtual monitoring locations to enable playback of the composite audio output channels 154.1 through 154.i through headphones or loudspeakers. In these embodiments, operational control flow 800 can generate these monitoring output signals to exhibit the one or more acoustical characteristics of the one or more virtual soundwaves at the one or more virtual monitoring locations from operation 808. This beneficially allows audio professionals to listen to, analyze, and refine the assignment, or mapping, of the discrete audio input channels 152.1 through 152.n onto the composite audio output channels 154.1 through 154.i t at the one or more virtual monitoring locations 704.1 through 704.m. In some embodiments, the operational control flow 800 can transcode the one or more monitoring output signals 156.1 through 156.k to arbitrary loudspeaker arrangements, custom or following loudspeaker layout standards as well as binauralized for headphone playback while keeping the temporal, spectral and spatial properties of the one or more virtual soundwaves as perceived at the one or more virtual monitoring locations intact. These one or more monitoring output signals beneficially allow audio professionals to physically hear the composite audio output channels 154.1 through 154.i. at the one or more virtual monitoring locations to evaluate the composite audio output channels 154.1 through 154.i as perceived at specific spatial locations associated with the one or more virtual monitoring locations 704.1 through 704.m in the real-world venue. As such, these audio professionals can evaluate the composite audio output channels 154.1 through 154.i as if the composite audio output channels 154.1 through 154.i were being played back at the real-world venue 102 without these audio professionals being physically present at the real-world venue 102. These capabilities enable remote auditory validation of system performance, support pre-venue calibration workflows, and promote accurate decision-making during the design and tuning stages without requiring physical presence at the real-world venue. As a result, these embodiments contribute to significant time and cost savings while enhancing the overall effectiveness and precision of audio system deployment.

Exemplary Computing Device that can be Incorporated within the Exemplary Audio System

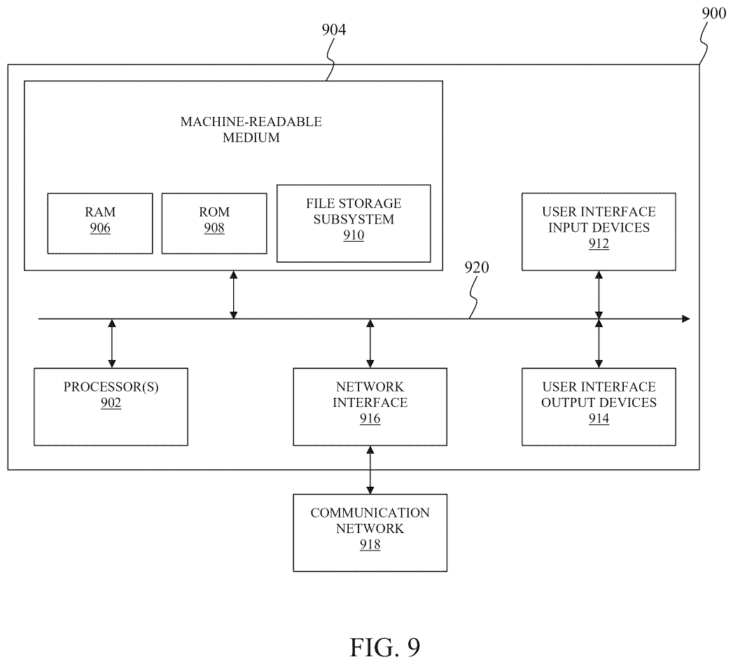

FIG. 9 graphically illustrates a simplified block diagram of a computing device that can be incorporated within the exemplary audio simulation system according to some embodiments of the present disclosure. The discussion of FIG. 9 to follow is intended to describe a representative computing device 900 that can be configured and programmed to implement, for example, the audio simulation workstation 104 as described above.

In the embodiment illustrated in FIG. 9, the computing device 900 includes one or more processors 902. In some embodiments, the one or more processors 902 can include, or can be, any of a microprocessor, graphics processing unit (GPU), or digital signal processor (DSP), as well as their functional or structural equivalents, such as, without limitation, an Application Specific Integrated Circuit (ASIC), a Field Programmable Gate Array (FPGA), a system-on-chip (SoC), or a neural processing unit (NPU). These processors may be selected based on performance requirements for real-time audio signal processing, waveform synthesis, digital filtering, or machine-learning inference used in interactive control environments. As used herein, the term “processor” signifies a tangible computing component or arrangement that performs data and signal processing operations by transforming input signals into output signals using a defined set of instructions or logic. The transformation may involve arithmetic operations, logical comparisons, memory accesses, and/or parallel data streaming. The data and information acted upon can be represented in physical form by signals such as, without limitation, voltages, currents, magnetic fields, optical pulses, or acoustic vibrations, which are capable of being sensed, measured, stored, transferred, and manipulated. The term “processor” may also refer to a single-core or multi-core processor, a distributed array of processor cores, or a multi-chip processing module. These can include general-purpose CPUs, specialized co-processors for multimedia acceleration, and digital audio engines integrated into system-on-chip platforms. In some implementations, the processor 902 may execute software or firmware components that support features such as, without limitation, real-time processing, simulation, data transformation, or analysis of signals or information. Additionally, the processor 902 may execute within a distributed computing environment, such as, without limitation, a virtualized infrastructure, a cloud computing platform, or a containerized environment running a software-as-a-service (SaaS) instance. For example, operations of the computing device 900 may be offloaded in whole or in part to remote compute nodes accessible via an application programming interface (API) over a network connection. This allows processing of high-complexity control signals and real-time response synchronization to be executed in scalable or latency-optimized environments.

In some embodiments, the computing device 900 can operate under a host operating system, which can include Microsoft Windows, MacOS by Apple, Linux distributions such as, without limitation, Ubuntu or Red Hat, UNIX variants, or real-time operating systems (RTOS). The computing device 900 may also include a Basic Input/Output System (BIOS), Unified Extensible Firmware Interface (UEFI), or similar low-level system firmware used to initialize and control hardware subsystems.

As illustrated in FIG. 9, the computing device 900 further includes a machine-readable medium 904, which may comprise one or more forms of tangible, non-transitory storage elements accessible by the processor 902. In some embodiments, the machine-readable medium 904 includes a main random-access memory (RAM) 906, a read-only memory (ROM) 908, and/or a file storage subsystem 910. The RAM 906 can include volatile memory such as, without limitation, static RAM (SRAM) or dynamic RAM (DRAM), which is used for storing temporary instruction sets and runtime data for execution. ROM 908 can include firmware-stored initialization code or bootloaders and is typically implemented using non-volatile technologies such as, without limitation, EEPROM, flash memory, or mask ROM. The file storage subsystem 910 provides persistent storage for system software, user data, control signal templates, and audio simulation parameters. It can include one or more mass storage devices such as, without limitation, solid-state drives (SSD), hard disk drives (HDD), optical drives, removable media such as, without limitation, flash drives or secure digital (SD) cards, and/or network-attached storage. The file storage subsystem 910 may support hierarchical file systems and may be accessible via high-speed internal interfaces such as, without limitation, Serial Advanced Technology Attachment (SATA), Peripheral Component Interconnect Express (PCIe), and/or Non-Volatile Memory Express (NVMe), or external interfaces such as, without limitation, Universal Serial Bus (USB) or Thunderbolt, among others.

The computing device 900 may also include one or more user interface input devices 912 and user interface output devices 914 for interaction with the user or operator. The user interface input devices 912 can include tactile, gesture-based, or biometric mechanisms such as, without limitation, an alphanumeric keyboard, touchscreen, capacitive touchpad, trackball, stylus, voice command system, microphone array, gesture camera, brain-computer interface, and/or electromyographic sensor, among others In some implementations, the computing device 900 can support multi-modal input techniques to allow simultaneous use of voice, gesture, or other input methods for controlling or interacting with system functions. These input devices 912 may be connected using wired interfaces such as, without limitation, USB, serial, and/or Inter-Integrated Circuit (I2C) or wireless protocols such as, without limitation, Bluetooth, Wi-Fi, or 9G. In some embodiments, these interfaces can allow interfaces may allow low-latency control over various parameters using real-time interactive input. The user interface output devices 914 can include visual, auditory, and/or haptic feedback mechanisms. Visual output may be provided by high-resolution displays such as, without limitation, Liquid Crystal Display (LCD), Organic Light-Emitting Diode (OLED), and/or Electronic Ink, among others, projection systems, or head-mounted displays (HMDs) for augmented or virtual reality environments. Audio output devices can include internal speakers, external sound systems, or specialized transducers such as, without limitation, ultrasonic emitters or bone-conduction devices. Haptic feedback may be delivered through vibration actuators or force-feedback mechanisms. These outputs may be used to convey feedback during waveform preview, device synchronization, or simulation of dynamic audio environments.

The computing device 900 may also include a network interface 916 to facilitate bidirectional communication with external systems and networks, including interface with a communication network 918. The network interface 916 may support various networking protocols and physical interfaces such as, without limitation, Universal Serial Bus (USB), Recommended Standard 232 (RS-232), RS-489, Universal Asynchronous Receiver-Transmitter (UART), Thunderbolt, Peripheral Component Interconnect Express (PCIe) Fire Wire (IEEE 1394), Ethernet (IEEE 802.3), Ethernet for Control Automation Technology, Ethernet for Control Automation Technology (EtherCAT), HDBaseT, Serial ATA (SATA), Small Computer System Interface (SCSI), Inter-Integrated Circuit (I2C), Serial Peripheral Interface (SPI), Bluetooth, Near Field Communication (NFC), Infrared, Wi-Fi (IEEE 802.11), Ultra-Wideband (UWB), Millimeter Wave Communication (mmWave), Light Fidelity (Li-Fi), Fifth Generation Mobile Networks (9G), Long-Term Evolution (4G LTE), Zigbee, and/or Z-Wave, among others. The network interface 916 may enable the computing device 900 to communicate with distributed audio control systems, cloud-based waveform libraries, remote signal processors, or external event systems such as, without limitation, performance automation frameworks. The communication network 918 can include a local area network (LAN), a wide area network (WAN), a mesh network, or a hybrid architecture. Security protocols such as, without limitation, Transport Layer Security (TLS), Secure Sockets Layer (SSL), or IPsec may be used to ensure data integrity and confidentiality. Virtual private network (VPN) tunnels and firewall rules may be implemented for secure communication with remote systems. Communication interfaces may utilize protocols such as, without limitation, Transmission Control Protocol/Internet Protocol (TCP/IP), User Datagram Protocol (UDP), HyperText Transfer Protocol/HyperText Transfer Protocol Secure (HTTP/S), Message Queuing Telemetry Transport (MQTT), WebSocket, and/or custom application-specific protocols for real-time data transfer, among others.

As illustrated in FIG. 9, the various components of the computing device 900, including, for example, the one or more processors 902, machine-readable medium 904, user interface input devices 912, user interface output devices 914, and network interface 916 are communicatively interconnected via a bus subsystem 920. The bus subsystem 920 can include one or more high-speed system buses, peripheral buses such as, without limitation, PCIe, memory buses, or internal chip interconnects. In some configurations, Direct Memory Access (DMA) channels may be used to facilitate high-throughput data transfer between memory and I/O subsystems without processor intervention, enabling lower latency and more efficient real-time audio processing. While shown as a unified bus for simplicity, the bus subsystem 920 can include multiple hierarchical or crossbar switch-based interconnects optimized for specific data paths, such as, without limitation, audio stream buffering, graphical rendering, or external signal routing.

### CONCLUSION

The Detailed Description referred to accompanying figures to illustrate exemplary embodiments consistent with the disclosure. References in the disclosure to “an exemplary embodiment” indicates that the exemplary embodiment described can include a particular feature, structure, or characteristic, but every exemplary embodiment may not necessarily include the particular feature, structure, or characteristic. Moreover, such phrases are not necessarily referring to the same exemplary embodiment. Further, any feature, structure, or characteristic described in connection with an exemplary embodiment can be included, independently or in any combination, with features, structures, or characteristics of other exemplary embodiments whether or not explicitly described.

The Detailed Description is not meant to limiting. Rather, the scope of the disclosure is defined only in accordance with the following claims and their equivalents. It is to be appreciated that the Detailed Description section, and not the Abstract section, is intended to be used to interpret the claims. The Abstract section can set forth one or more, but not all exemplary embodiments, of the disclosure, and thus, are not intended to limit the disclosure and the following claims and their equivalents in any way.

The exemplary embodiments described within the disclosure have been provided for illustrative purposes and are not intended to be limiting. Other exemplary embodiments are possible, and modifications can be made to the exemplary embodiments while remaining within the spirit and scope of the disclosure. The disclosure has been described with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

Embodiments of the disclosure can be implemented in hardware, firmware, software application, or any combination thereof. Embodiments of the disclosure can also be implemented as instructions stored on a machine-readable medium, which can be read and executed by one or more processors. A machine-readable medium can include any mechanism for storing or transmitting information in a form readable by a machine (e.g., a computing circuitry). For example, a machine-readable medium can include non-transitory machine-readable mediums such as, without limitation, read only memory (ROM); random access memory (RAM); magnetic disk storage media; optical storage media; flash memory devices; and others. As another example, the machine-readable medium can include transitory machine-readable medium such as, without limitation, electrical, optical, acoustical, or other forms of propagated signals (e.g., carrier waves, infrared signals, digital signals, etc.). Further, firmware, software application, routines, instructions can be described herein as performing certain actions. However, it should be appreciated that such descriptions are merely for convenience and that such actions in fact result from computing devices, processors, controllers, or other devices executing the firmware, software application, routines, instructions, etc.

The Detailed Description of the exemplary embodiments fully revealed the general nature of the disclosure that others can, by applying knowledge of those skilled in relevant art(s), readily modify and/or adapt for applications such exemplary embodiments, without undue experimentation, without departing from the spirit and scope of the disclosure. Therefore, such adaptations and modifications are intended to be within the meaning and plurality of equivalents of the exemplary embodiments based upon the teaching and guidance presented herein. It is to be understood that the phraseology or terminology herein is for the purpose of description and not of limitation, such that the terminology or phraseology of the present specification is to be interpreted by those skilled in relevant art(s) in light of the teachings herein.

What is claimed is:

1. A method for mapping audio channels for playback in a real-world venue, the method comprising:
selecting, by an audio simulation workstation, a virtual mapping location for an audio input channel within a virtual model of a real-world venue, the virtual model including a plurality of virtual loudspeakers that correspond to a plurality of real-world loudspeakers incorporated within the real-world venue;
assigning, by the audio simulation workstation, the audio input channel to the virtual mapping location;
identifying, by the audio simulation workstation, a virtual loudspeaker from among the plurality of virtual loudspeakers that corresponds to the virtual mapping location;
associating, by the audio simulation workstation, the virtual loudspeaker with a real-world loudspeaker from among the plurality of real-world loudspeakers that is incorporated within the real-world venue; and
assigning, by the audio simulation workstation, the real-world loudspeaker to an audio output channel to map the audio input channel to the audio output channel.

2. The method of claim 1, wherein the selecting comprises providing, by the audio simulation workstation, a graphical user interface (GUI) having a graphical representation of the virtual model of the real-world venue and a virtual pointing device that is controllable by a user to select the virtual mapping location within the virtual model.

3. The method of claim 2, wherein the assigning the audio input channel comprises incorporating a point-and-click or drag-and-drop interaction on the GUI to assign the audio input channel to the virtual mapping location.

4. The method of claim 3, further comprising highlighting the virtual loudspeaker within the graphical representation of the virtual model.

5. The method of claim 2, further comprising:
overlaying a video or an image onto the virtual model of the real-world venue, and
synchronizing playback of the video or the image with playback of the one or more audio output channels.

6. The method of claim 1, further comprising:
rendering the plurality of virtual loudspeakers within the virtual model of the real-world venue; and
visually emphasizing, in the virtual model, the virtual loudspeaker that corresponds to the virtual mapping location.

7. The method of claim 1, wherein the selecting the virtual mapping location, the assigning the audio input channel, the identifying the virtual loudspeaker, the associating the virtual loudspeaker, and the assigning the real-world loudspeaker are performed remotely without physical presence at the real-world venue.

8. An audio simulation workstation for mapping audio channels for playback in a real-world venue, the audio simulation workstation comprising:
a memory configured to store an audio mapping tool; and
a processor configured to execute the audio mapping tool, the audio mapping tool, when executed by the processor, configuring the processor to:
select a virtual mapping location for an audio input channel within a virtual model of a real-world venue, the virtual model including a plurality of virtual loudspeakers that correspond to a plurality of real-world loudspeakers incorporated within the real-world venue,
assign the audio input channel to the virtual mapping location,
identify a virtual loudspeaker from among the plurality of virtual loudspeakers that corresponds to the virtual mapping location,
associate the virtual loudspeaker with a real-world loudspeaker from among the plurality of real-world loudspeakers that is incorporated within the real-world venue, and
assign the real-world loudspeaker to an audio output channel to map the audio input channel to the audio output channel.

9. The audio simulation workstation of claim 8, wherein the audio mapping tool, when executed by the processor, configures the processor to provide a graphical user interface (GUI) having a graphical representation of the virtual model of the real-world venue and a virtual pointing device that is controllable by a user to select the virtual mapping location within the virtual model.

10. The audio simulation workstation of claim 9, wherein the audio mapping tool, when executed by the processor, configures the processor to incorporate a point-and-click or drag-and-drop interaction on the GUI to assign the audio input channel to the virtual mapping location.

11. The audio simulation workstation of claim 10, wherein the audio mapping tool, when executed by the processor, further configures the processor to highlight the virtual loudspeaker within the graphical representation of the virtual model.

12. The audio simulation workstation of claim 9, wherein the audio mapping tool, when executed by the processor, further configures the processor to:
overlay a video or an image onto the virtual model of the real-world venue; and
synchronize playback of the video or the image with playback of the one or more audio output channels.

13. The audio simulation workstation of claim 8, wherein the audio mapping tool, when executed by the processor, further configures the processor to:
render the plurality of virtual loudspeakers within the virtual model of the real-world venue; and
visually emphasize, in the virtual model, the virtual loudspeaker that corresponds to the virtual mapping location.

14. The audio simulation workstation of claim 8, wherein the audio mapping tool, when executed by the processor, configures the processor to perform the selecting the virtual mapping location, the assigning the audio input channel, the identifying the virtual loudspeaker, the associating the virtual loudspeaker, and the assigning the real-world loudspeaker are performed remotely without physical presence at the real-world venue.

15. A venue, comprising:
a plurality of real-world loudspeakers, disposed throughout the venue, associated with a plurality of audio output channels; and
an audio simulation workstation configured to:
select a virtual mapping location for an audio input channel within a virtual model of a real-world venue, the virtual model including a plurality of virtual loudspeakers that corresponds to a plurality of real-world loudspeakers incorporated within the real-world venue,
assign the audio input channel to the virtual mapping location,
identify a virtual loudspeaker from among the plurality of virtual loudspeakers that corresponds to the virtual mapping location,
associate the virtual loudspeaker with a real-world loudspeaker from among the plurality of real-world loudspeakers that is incorporated within the real-world venue, and
assign the real-world loudspeaker to an audio output channel to map the audio input channel to the audio output channel.

16. The venue of claim 15, wherein the audio simulation workstation is configured to provide a graphical user interface (GUI) having a graphical representation of the virtual model of the real-world venue and a virtual pointing device that is controllable by a user to select the virtual mapping location within the virtual model.

17. The venue of claim 16, wherein the audio simulation workstation is configured to incorporate a point-and-click or drag-and-drop interaction on the GUI to assign the audio input channel to the virtual mapping location.

18. The venue of claim 17, the audio simulation workstation is further configured to highlight the virtual loudspeaker within the graphical representation of the virtual model.

19. The venue of claim 16, wherein the audio simulation workstation is further configured to:
overlay a video or an image onto the virtual model of the real-world venue; and
synchronize playback of the video or the image with playback of the one or more audio output channels.

20. The venue of claim 15, the audio simulation workstation is further configured to:
render the plurality of virtual loudspeakers within the virtual model of the real-world venue; and
visually emphasize, in the virtual model, the virtual loudspeaker that corresponds to the virtual mapping location.
